(19) United States
(12) Patent Application Publication
(10) Pub. No.: US 2020/0316914 A1
(43) Pub. Date: Oct. 8, 2020

(54) LAMINATE, COMPOSITE, AND METHOD FOR PRODUCING COMPOSITE

(71) Applicant: FUJIFILM Corporation, Tokyo (JP)

(72) Inventor: Junji KAWAGUCHI, Shizuoka (JP)

(73) Assignee: FUJIFILM Corporation, Tokyo (JP)

(21) Appl. No.: 16/910,555

(22) Filed: Jun. 24, 2020

Related U.S. Application Data
(63) Continuation of application No. PCT/JP2018/047000, filed on Dec. 20, 2018.

(30) Foreign Application Priority Data
Jan. 17, 2018 (JP) 2018-005348

(51) Int. Cl. B32B 15/09; G03F 7/023; B32B 15/20; B32B 15/098; B32B 3/26

(52) U.S. Cl. CPC B32B 15/09; G03F 7/023; G03F 7/2004; B32B 15/098; B32B 3/266; B32B 15/20

(57) ABSTRACT

Provided are a laminate having excellent appearance such as tint and excellent light transmittance, a composite, and a method for producing a composite. The laminate includes a metal foil having a plurality of through-holes penetrating therethrough in a thickness direction, and a positive photosensitive resin layer provided on at least one surface of the metal foil, in which, in the metal foil, an average opening diameter of the through-holes is 0.1 to 100 μm and an average opening ratio determined by the through-holes is 0.1% to 90%. The composite includes a laminate, in which the positive photosensitive resin layer has a plurality of through-holes penetrating therethrough in a thickness direction, the average opening diameter of the through-holes is 0.1 to 100 μm, and the average opening ratio of the through-holes is 0.1% to 90%.

### CROSS-REFERENCE TO RELATED APPLICATIONS

This application is a Continuation of PCT International Application No. PCT/JP2018/047000 filed on Dec. 20, 2018, which claims priority under 35 U.S.C. § 119(a) to Japanese Patent Application No. 2018-005348 filed on Jan. 17, 2018. The above application is hereby expressly incorporated by reference, in its entirety, into the present application.

### BACKGROUND OF THE INVENTION

### 1. Field of the Invention

The present invention relates to a laminate having a metal foil provided with through-holes, a composite, and a method for producing a composite. The present invention particularly relates to a laminate having a positive photosensitive resin layer formed on a metal foil provided with through-holes and having various functions while maintaining transmittance, a composite, and a method for producing a composite.

### 2. Description of the Related Art

Conventionally, it has been known to enhance the decorativeness of a resin molded article by vapor deposition of a metal on a surface of the resin molded article to give a metallic tone or a half mirror tone.

For example, WO2017/150099A discloses a composite for forming a metal-like decorative body including an aluminum substrate having a plurality of through-holes in a thickness direction and a resin layer provided on at least one surface of the aluminum substrate, in which an average opening diameter of the through-holes is 0.1 to 100 μm and an average opening ratio determined by the through-holes is 1% to 50%, as a composite for forming a metal-like decorative body with which a molded article having excellent appearance and excellent light transmittance can be produced.

### SUMMARY OF THE INVENTION

The composite for forming a metal-like decorative body of WO2017/150099A described above makes it possible to produce a molded article having excellent appearance and excellent light transmittance, but the produced molded article is required to be more excellent in appearance such as tint and light transmittance and there is no such article at present.

An object of the present invention is to provide a laminate having excellent appearance such as tint and excellent light transmittance, a composite, and a method for producing a composite.

In order to achieve the foregoing object, the present invention provides a laminate comprising:

a metal foil having a plurality of through-holes penetrating therethrough in a thickness direction; and

a positive photosensitive resin layer provided on at least one surface of the metal foil,

in which, in the metal foil, an average opening diameter of the through-holes is 0.1 to 100 μm and an average opening ratio determined by the through-holes is 0.1% to 90%.

Further, the present invention provides a laminate comprising:

a metal foil having a plurality of through-holes penetrating therethrough in a thickness direction;

a resin layer provided on one surface of the metal foil; and

a positive photosensitive resin layer provided on the other surface where the resin layer is not provided among both surfaces of the metal foil,

in which, in the metal foil, an average opening diameter of the through-holes is 0.1 to 100 μm and an average opening ratio determined by the through-holes is 0.1% to 90%.

The positive photosensitive resin layer preferably contains two compounds of a phenol type resin (A) and o-naphthoquinonediazide or an infrared absorber (B).

The positive photosensitive resin layer preferably contains a coloring material.

The coloring material preferably contains a dye and a pigment.

The metal foil preferably has an average thickness of 5 to 1000 μm.

The metal foil is preferably a foil selected from the group consisting of an aluminum foil, a copper foil, a silver foil, a gold foil, a platinum foil, a stainless steel foil, a titanium foil, a tantalum foil, a molybdenum foil, a niobium foil, a zirconium foil, a tungsten foil, a beryllium copper foil, a phosphor bronze foil, a brass foil, a nickel silver foil, a tin foil, a lead foil, a zinc foil, a solder foil, an iron foil, a nickel foil, a Permalloy foil, a nichrome foil, an Alloy 42 foil, a Kovar foil, a Monel foil, an Inconel foil, and a Hastelloy foil, or a foil in which a foil selected from the above group and a foil of a metal of a type different from the foil selected from the above group are laminated.

The present invention provides a composite comprising:

the above-mentioned laminate of the present invention,

in which the positive photosensitive resin layer has a plurality of through-holes penetrating therethrough in a thickness direction, an average opening diameter of the through-holes is 0.1 to 100 μm, and an average opening ratio of the through-holes is 0.1% to 90%.

The light transmittance is preferably 0.1% to 90%.

Further, the present invention provides a method for producing a composite comprising a metal foil having a plurality of through-holes penetrating therethrough in a thickness direction, an average opening diameter of the through-holes of 0.1 to 100 μm, and an average opening ratio determined by the through-holes of 0.1% to 90%, and a positive photosensitive resin layer provided on at least one surface of the metal foil, comprising:

exposing the positive photosensitive resin layer from a metal foil side; and

developing the exposed positive photosensitive resin layer with an alkaline aqueous solution.

For the exposure, ultraviolet light or infrared light is preferably used.

According to the present invention, there is provided a composite having excellent appearance such as tint and excellent light transmittance. In addition, there is provided a laminate that becomes a composite having excellent appearance such as tint and excellent light transmittance.

In addition, there is provided a method for producing a composite having excellent appearance such as tint and excellent light transmittance.

### BRIEF DESCRIPTION OF THE DRAWINGS

FIG. 1 is a schematic plan view showing a first example of a composite according to an embodiment of the present invention.

FIG. 2 is a schematic cross-sectional view showing the first example of the composite according to the embodiment of the present invention.

FIG. 3 is a cross-sectional view showing an example of a metal foil for describing an average effective diameter of through-holes of the composite according to the embodiment of the present invention.

FIG. 4 is a cross-sectional view showing another example of the metal foil for describing the average effective diameter of the through-holes of the composite according to the embodiment of the present invention.

FIG. 5 is a schematic cross-sectional view showing a second example of the composite according to the embodiment of the present invention.

FIG. 6 is a schematic cross-sectional view showing a third example of the composite according to the embodiment of the present invention.

FIG. 7 is a schematic cross-sectional view showing one step of a first example of a method for producing a composite according to the embodiment of the present invention.

FIG. 8 is a schematic cross-sectional view showing one step of the first example of the method for producing a composite according to the embodiment of the present invention.

FIG. 9 is a schematic cross-sectional view showing one step of the first example of the method for producing a composite according to the embodiment of the present invention.

FIG. 10 is a schematic cross-sectional view showing one step of the first example of the method for producing a composite according to the embodiment of the present invention.

FIG. 11 is a schematic cross-sectional view showing one step of the first example of the method for producing a composite according to the embodiment of the present invention.

FIG. 12 is a schematic cross-sectional view showing one step of a second example of the method for producing a composite according to the embodiment of the present invention.

FIG. 13 is a schematic cross-sectional view showing one step of the second example of the method for producing a composite according to the embodiment of the present invention.

FIG. 14 is a schematic cross-sectional view showing one step of the second example of the method for producing a composite according to the embodiment of the present invention.

FIG. 15 is a schematic cross-sectional view showing one step of a third example of the method for producing a composite according to the embodiment of the present invention.

FIG. 16 is a schematic cross-sectional view showing one step of the third example of the method for producing a composite according to the embodiment of the present invention.

FIG. 17 is a schematic cross-sectional view showing one step of the third example of the method for producing a composite according to the embodiment of the present invention.

FIG. 18 is a schematic cross-sectional view showing one step of the third example of the method for producing a composite according to the embodiment of the present invention.

FIG. 19 is a schematic cross-sectional view showing one step of another example of a method for producing a through-hole in a metal foil of the composite according to the embodiment of the present invention.

FIG. 20 is a schematic cross-sectional view showing one step of another example of the method for producing a through-hole in the metal foil of the composite according to the embodiment of the present invention.

FIG. 21 is a schematic cross-sectional view showing one step of another example of the method for producing a through-hole in the metal foil of the composite according to the embodiment of the present invention.

FIG. 22 is a schematic cross-sectional view showing one step of another example of the method for producing a through-hole in the metal foil of the composite according to the embodiment of the present invention.

### DESCRIPTION OF THE PREFERRED EMBODIMENTS

Hereinafter, a laminate, a composite, and a method for producing a composite according to the embodiment of the present invention will be described in detail with reference to suitable embodiments shown in the accompanying drawings.

Note that the drawings described below are illustrative for explaining the present invention, and the present invention is not limited to the drawings shown below.

In the following, the term “to” indicating a numerical range includes numerical values described on both sides thereof. For example, in a case where ε is a numerical value α to a numerical value β, the range of ε is a range including the numerical value α and the numerical value β, which is α≤ε≤β in mathematical symbols.

Unless otherwise specified, “parallel”, “perpendicular”, and the like include error ranges generally accepted in the relevant technical field.

[Composite]

The first composite includes a metal foil having a plurality of through-holes penetrating therethrough in a thickness direction, and a positive photosensitive resin layer provided on at least one surface of the metal foil,

in which, in the metal foil, an average opening diameter of the through-holes is 0.1 to 100 μm and an average opening ratio determined by the through-holes is 1% to 50%, and

the positive photosensitive resin layer has a plurality of through-holes penetrating therethrough in a thickness direction, in which the average opening diameter of the through-holes is 0.1 to 100 μm and the average opening ratio of the through-holes is 0.1% to 90%.

The structure including a metal foil having a plurality of through-holes penetrating therethrough in a thickness direction, and a positive photosensitive resin layer provided on at least one surface of the metal foil, in which, in the metal foil, an average opening diameter of the through-holes is 0.1 to 100 μm and an average opening ratio determined by the through-holes is 1% to 50% is referred to as a laminate. The laminate is a pre-composite stage and has no through-holes in the positive photosensitive resin layer. A composite is obtained by processing the laminate.

The second composite includes a metal foil having a plurality of through-holes penetrating therethrough in a thickness direction, a resin layer provided on one surface of the metal foil, and a positive photosensitive resin layer provided on the other surface of the metal foil,

in which, in the metal foil, an average opening diameter of the through-holes is 0.1 to 100 μm and an average opening ratio determined by the through-holes is 1% to 50%, and

the positive photosensitive resin layer has a plurality of through-holes penetrating therethrough in a thickness direction, in which the average opening diameter of the through-holes is 0.1 to 100 μm and the average opening ratio of the through-holes is 0.1% to 90%.

The structure including a metal foil having a plurality of through-holes penetrating therethrough in a thickness direction, a resin layer provided on one surface of the metal foil, and a positive photosensitive resin layer provided on the other surface of the metal foil, in which, in the metal foil, an average opening diameter of the through-holes is 0.1 to 100 μm and an average opening ratio determined by the through-holes is 1% to 50% is referred to as a laminate. The laminate is a pre-composite stage and has no through-holes in the positive photosensitive resin layer. A composite is obtained by processing the laminate.

Note that the laminate has the same configuration as the first composite and the second composite except that the positive photosensitive resin layer has no through-holes as described above; and the configuration and composition of the metal foil and the positive photosensitive resin layer are the same.

In the present invention, excellent appearance such as tint and excellent light transmittance are achieved by including a metal foil having an average opening diameter and an average opening ratio of the through-holes within the above-mentioned ranges, and a positive photosensitive resin layer provided on at least one surface of the metal foil.

Although the reason for such an effect is not clear in detail, the present inventors speculate as follows.

It is considered that, in a case where the average opening diameter and the average opening ratio of the through-holes present in the metal foil are within the above-mentioned ranges, it becomes difficult to visually confirm the presence of the through-holes, while the positive photosensitive resin layer is visible, and therefore, light could be transmitted without impairing the appearance such as tint.

In addition, it is considered that, by including a positive photosensitive resin layer, excellent appearance such as tint and excellent light transmittance are achieved, various functions are maintained while having transmittance, and processing into a molded article such as a metal-like decorative body used for lighting applications has become easier.

The average opening diameter of the through-holes is obtained in such a manner that the surface of the metal foil is imaged from directly above at a magnification of 100 to 10,000 times using a high-resolution scanning electron microscope, at least 20 through-holes whose periphery is connected in a ring shape are extracted in the captured image obtained using the high-resolution scanning electron microscope, diameters of the extracted through-holes are read out to obtain opening diameters, and the average value of the opening diameters is calculated as the average opening diameter.

For the magnification, a magnification in the above-mentioned range can be appropriately selected so that a captured image from which 20 or more through-holes can be extracted is obtained. For the opening diameter, a maximum value of a distance between the ends of the through-hole portion was measured. That is, the shape of the opening of the through-hole is not limited to the substantially circular shape, and therefore in a case where the shape of the opening is non-circular, the maximum value of the distance between the ends of the through-hole portion is defined as the opening diameter. Therefore, for example, even in a case of a through-hole having a shape in which two or more through-holes are integrated, this is regarded as one through-hole, and the maximum value of the distance between the ends of the through-hole portion is defined as the opening diameter.

In addition, the average opening ratio determined by the through-holes is determined as follows. A parallel light optical unit is installed on one surface side of the metal foil, parallel light is allowed to transmit therethrough, the surface of the metal foil is imaged from the other surface of the metal foil with an optical microscope at a magnification of 100 times, and the captured image is obtained as a photograph or digital image data. For a visual field (5 places) of 100 mm×75 mm in the range of 10 cm×10 cm of the obtained captured image, the ratio (opening area/geometric area) is calculated from the sum of the opening areas of the through-holes projected by the transmitted parallel light and the area of the visual field (geometric area), and then the average value in each visual field (5 places) is calculated as the average opening ratio.

Hereinafter, the composite will be specifically described with reference to the drawings.

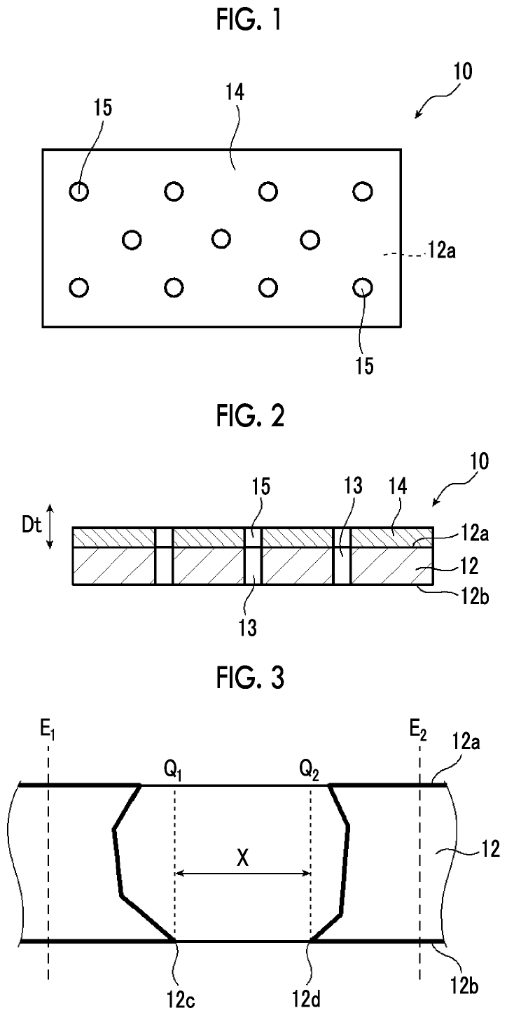

FIG. 1 is a schematic plan view showing a first example of a composite according to an embodiment of the present invention, and FIG. 2 is a schematic cross-sectional view showing the first example of the composite according to the embodiment of the present invention.

As shown in FIGS. 1 and 2, a composite 10 includes a metal foil 12 having a plurality of through-holes 13 penetrating therethrough in a thickness direction Dt, and a positive photosensitive resin layer 14 provided on at least one surface 12a of the metal foil 12.

In the metal foil 12, the average opening diameter of the through-holes 13 is 0.1 to 100 μm, and the average opening ratio determined by the through-holes 13 is 1% to 50%.

The positive photosensitive resin layer 14 has a plurality of through-holes 15 penetrating therethrough in a thickness direction Dt, in which the average opening diameter of the through-holes 15 is 0.1 to 100 μm and the average opening ratio of the through-holes 15 is 0.1% to 90%.

As shown in FIG. 2, the through-hole 13 of the metal foil 12 and the through-hole 15 of the positive photosensitive resin layer 14 are arranged so as to coincide with each other and therefore the through-hole 13 of the metal foil 12 and the through-hole 15 of the positive photosensitive resin layer 14 constitute one through-hole.

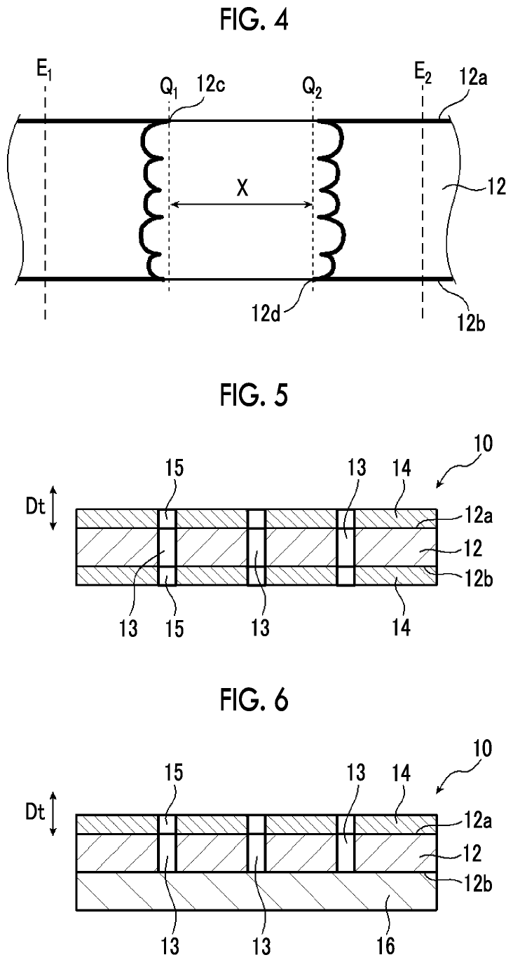

Here, the composite 10 shown in FIGS. 1 and 2 has a configuration in which the hole wall surface of the through-hole 13 has a surface perpendicular to the surface of the metal foil 12, but as shown in FIGS. 3 and 4 which will be described later, the composite 10 may have a configuration in which the hole wall surface of the through-hole 13 has a concavo-convex shape.

FIG. 3 is a cross-sectional view showing an example of a metal foil for describing an average effective diameter of through-holes of the composite according to the embodiment of the present invention, and FIG. 4 is a cross-sectional view showing another example of the metal foil for describing the average effective diameter of the through-holes of the composite according to the embodiment of the present invention.

The average effective diameter refers to the shortest distance between the hole wall surfaces of the through-holes in a cross section cut in a direction perpendicular to the surface of the metal foil, and as shown in FIGS. 3 and 4, the average effective diameter refers to an average value of a distance X between a perpendicular line Q₁ at a point 12c where the distance from a reference line E₁ is the largest on a left hole wall surface of the through-hole 13 of the metal foil 12 and a perpendicular line Q₂ at a point 12d where the distance from a reference line E₂ is the largest on a right hole wall surface of the through-hole 13.

In the present invention, the average effective diameter is determined as follows. A parallel light optical unit is installed on one surface side of the metal foil, parallel light is allowed to transmit therethrough, the surface of the metal foil is imaged from the other surface of the metal foil with an optical microscope at a magnification of 100 times, and the captured image is obtained as a photograph or digital image data. For a visual field (5 places) of 100 mm×75 mm in the range of 10 cm×10 cm of the obtained captured image, 20 through-holes projected by the transmitted parallel light are extracted in each visual field. The diameters of a total of 100 extracted through-holes are measured, and the average value thereof is calculated as the average effective diameter.

In the composite 10 shown in FIGS. 1 and 2, the positive photosensitive resin layer 14 is not provided on the other surface 12b of the metal foil 12, and the positive photosensitive resin layer 14 is provided only on one surface 12a. However, it is not limited to this configuration.

For example, as in the composite 10 shown in FIG. 5, the composite 10 may have a configuration in which the positive photosensitive resin layer 14 is provided on each of one surface 12a and the other surface 12b of the metal foil 12, that is, a configuration in which the positive photosensitive resin layer 14 is provided on both surfaces of the metal foil 12. In this case, the position of the through-hole 15 of the positive photosensitive resin layer 14 provided on each of the surfaces 12a and 12b and the position of the through-hole 13 of the metal foil 12 coincide with each other and therefore the through-hole 15 of the positive photosensitive resin layer 14 and the through-hole 13 of the metal foil 12 constitute one through-hole.

In addition, as in the composite 10 shown in FIG. 6, the composite 10 may have a configuration in which a resin layer 16 is provided on the other surface 12b of the metal foil 12 and the positive photosensitive resin layer 14 is provided on the one surface 12a of the metal foil 12. In the composite 10 shown in FIG. 6, the arrangement positions of the resin layer 16 and the positive photosensitive resin layer 14 may be reversed to each other. The resin layer 16 has a configuration in which no through-hole is provided. In this case, the position of the through-hole 15 of the positive photosensitive resin layer 14 provided on the surface 12a and the position of the through-hole 13 of the metal foil 12 coincide with each other and therefore the through-hole 15 of the positive photosensitive resin layer 14 and the through-hole 13 of the metal foil 12 constitute one through-hole.

FIG. 5 is a schematic cross-sectional view showing a second example of the composite according to the embodiment of the present invention, and FIG. 6 is a schematic cross-sectional view showing a third example of the composite according to the embodiment of the present invention.

Hereinafter, the laminate and the composite will be described in more detail.

[Metal Foil]

The metal foil of the laminate and the composite is not particularly limited as long as it has a through-hole. The metal foil is preferably a foil made of at least one of a metal, an alloy, or a metal compound, which is capable of easily forming a through-hole having the above-mentioned average opening diameter and average opening ratio, and more preferably a foil made of a metal.

In addition, the metal foil is also preferably a metal foil containing a metal atom that dissolves in an etchant used in a through-hole forming step which will be described later. In addition, the foil is referred to as a metal foil, regardless of whether it is made of a metal, an alloy, or a metal compound.

Specific examples of the metal foil include an aluminum foil, a copper foil, a silver foil, a gold foil, a platinum foil, a stainless steel foil, a titanium foil, a tantalum foil, a molybdenum foil, a niobium foil, a zirconium foil, a tungsten foil, a beryllium copper foil, a phosphor bronze foil, a brass foil, a nickel silver foil, a tin foil, a lead foil, a zinc foil, a solder foil, an iron foil, a nickel foil, a Permalloy foil, a nichrome foil, an Alloy 42 foil, a Kovar foil, a Monel foil, an Inconel foil, and a Hastelloy foil.

In addition, the metal foil may be a foil in which a foil selected from the above group of metals and a foil of a metal of a type different from the foil selected from the above group are laminated. The metal foil may be a foil in which two or more different metal foils are laminated.

The method of laminating the metal foil is not particularly limited, but is preferably plating or a cladding material. The metal used for plating is not particularly limited as long as it is a metal containing a metal atom that dissolves in an etchant, but is preferably a metal. Examples of the plating species include nickel, chromium, cobalt, iron, zinc, tin, copper, silver, gold, platinum, palladium, and aluminum.

The plating method is not particularly limited, and any of electroless plating, electrolytic plating, hot dip plating, and chemical conversion treatment is used.

The metal used for forming the cladding material on the metal foil is not particularly limited as long as it is a metal containing a metal atom that dissolves in an etchant, but is preferably a metal. Examples of the metal species include metals used for the above-mentioned metal foil.

<Thickness of Metal Foil>

The average thickness of the above-mentioned metal foil is preferably 5 to 1000 μm and, from the viewpoint of handleability, more preferably 5 to 50 μm and still more preferably 8 to 30 μm. Note that the average thickness of the metal foil is an average value of thicknesses measured at any five points using a contact type film thickness meter (digital electronic micrometer).

<Aluminum Foil>

In a case where an aluminum foil is used as the metal foil, a known aluminum alloy, for example, 1000 series such as Aluminum 1085, 3000 series such as Aluminum 3003, or 8000 series such as Aluminum 8021, can be used as the aluminum foil. As such an aluminum alloy, for example, an aluminum alloy having an alloy number shown in Table 1 below can be used.

TABLE 1

| | Si | Fe | Cu |
|---|---|---|---|
| Alloy No. | (% by mass) | (% by mass) | (% by mass) |
| 1085 | 0.02 | 0.04 | <0.01 |
| 1N30 | 0.11 | 0.45 | 0.02 |
| 8021 | 0.04 | 1.44 | <0.01 |
| 3003 | 0.60 | 0.70 | 0.10 |

<Through-Hole>

As described above, the through-holes of the metal foil have an average opening diameter of the through-holes of 0.1 to 100 μm and an average opening ratio determined by the through-holes of 0.1% to 90%.

Here, the average opening diameter of the through-holes is preferably 1 to 45 μm, more preferably 1 to 40 μm, and still more preferably 1 to 30 μm, from the viewpoint of tensile strength, transmission characteristics, and the like.

In addition, the average opening ratio determined by the through-holes is preferably 2% to 45%, more preferably 2% to 30%, and particularly preferably 2% to 20%, from the viewpoint of tensile strength, transmission characteristics, and the like.

In the present invention, the average effective diameter of the through-holes in a cross section cut in a direction perpendicular to the surface of the metal foil is preferably 700 nm or more, more preferably 800 nm or more, and still more preferably 1 to 100 μm, from the viewpoint that the light transmittance is further improved.

[Positive Photosensitive Resin Layer]

The positive photosensitive resin layer imparts color to the composite. The thickness of the positive photosensitive resin layer is preferably 0.1 to 100 μm, more preferably 0.5 to 50 μm, and most preferably 1 to 30 μm.

The thickness of the positive photosensitive resin layer is an average value of thicknesses measured at any five points of the layer corresponding to the positive photosensitive resin layer in a case where the composite is cut using a microtome and the cross section is observed with an electron microscope.

The wavelength of the exposure light and the like for the positive photosensitive resin layer are not particularly limited as long as the through-holes can be formed by exposure and development. The positive photosensitive resin layer is exposed with, for example, infrared light or ultraviolet light and is developed with an alkaline aqueous solution.

The positive photosensitive resin layer is not particularly limited in its configuration as long as it can be exposed with, for example, infrared light or ultraviolet light, and a known positive photosensitive resin layer can be appropriately used.

Hereinafter, specific examples of the positive photosensitive resin layer will be described.

The positive photosensitive resin layer preferably contains two compounds of a phenol type resin (A) and o-naphthoquinonediazide or an infrared absorber (B). In addition, the positive photosensitive resin layer may contain a coloring material. The coloring material may include a dye and a pigment.

[Phenol Type Resin]

As for the phenol type resin (A), examples of an alkaline water-soluble polymer having a phenol group (—Ar—OH) include a novolak resin produced from one or more of phenols (such as phenol, o-cresol, m-cresol, p-cresol, and xylenol) and aldehydes (such as formaldehyde and paraformaldehyde), and a polycondensate of pyrogallol and acetone. Further, a copolymer obtained by copolymerizing a compound having a phenol group can also be mentioned. Examples of the compound having a phenol group include acrylamide, methacrylamide, acrylate, methacrylate, and hydroxystyrene which have a phenol group.

Specific examples of the compound having a phenol group include N-(2-hydroxyphenyl)acrylamide, N-(3-hydroxyphenyl)acrylamide, N-(4-hydroxyphenyl)acrylamide, N-(2-hydroxyphenyl)methacrylamide, N-(3-hydroxyphenyl)methacrylamide, N-(4-hydroxyphenyl)methacrylamide, o-hydroxyphenyl acrylate, m-hydroxyphenyl acrylate, p-hydroxyphenyl acrylate, o-hydroxyphenyl methacrylate, m-hydroxyphenyl methacrylate, p-hydroxyphenyl methacrylate, o-hydroxystyrene, m-hydroxystyrene, p-hydroxystyrene, 2-(2-hydroxyphenyl)ethyl acrylate, 2-(3-hydroxyphenyl)ethyl acrylate, 2-(4-hydroxyphenyl)ethyl acrylate, 2-(2-hydroxyphenyl)ethyl methacrylate, 2-(3-hydroxyphenyl)ethyl methacrylate, and 2-(4-hydroxyphenyl)ethyl methacrylate.

Among these, a novolak resin or a copolymer of hydroxystyrene is preferable. Examples of commercially available products of the copolymer of hydroxystyrene include MARUKA LYNCUR MH-2, MARUKA LYNCUR MS-4, MARUKA LYNCUR MS-2, and MARUKA LYNCUR MS-1 (all manufactured by Maruzen Petrochemical Co., Ltd.), and VP-8000 and VP-15000 (both manufactured by Nippon Soda Co., Ltd.).

The above-mentioned positive photosensitive resin layer may contain a polymer component, and the polymer component preferably has a weight-average molecular weight in the range of 1.0×10³ to 2.0×10⁵ and a number-average molecular weight in the range of 5.0×10² to 1.0×10⁵, regardless of a homopolymer or a copolymer. In addition, a polymer component having a polydispersity (weight-average molecular weight/number-average molecular weight) of 1.1 to 10 is preferable.

In a case where a copolymer is used as the polymer component, a blending weight ratio of a minimum constitutional unit that constitutes the main chain and/or side chain thereof and is derived from a compound having an acidic group to the other minimum constitutional unit that constitutes a part of the main chain and/or the side chain and does not contain an acidic group is preferably in the range of 50:50 to 5:95 and more preferably in the range of 40:60 to 10:90.

The above-mentioned polymer components may each be used alone or in combination of two or more thereof, and are preferably used in the range of 30% to 99% by mass, more preferably in the range of 40% to 95% by mass, and particularly preferably in the range of 50% to 90% by mass with respect to the total solid content contained in the composition.

(Surfactant)

From the viewpoint of coating properties, a nonionic surfactant as described in JP1987-251740A (JP-S62-251740A) and/or JP1991-208514A (JP-H03-208514A) or an amphoteric surfactant as described in JP1984-121044A (JP-S59-121044A) and/or JP1992-013149A (JP-H04-013149A) can be added to the above-mentioned positive photosensitive resin layer.

Specific examples of the nonionic surfactant include sorbitan tristearate, sorbitan monopalmitate, sorbitan triolate, monoglyceride stearate, and/or polyoxyethylene nonyl phenyl ether.

Specific examples of the amphoteric surfactant include alkyl di(aminoethyl)glycine, alkyl polyaminoethyl glycine hydrochloride, 2-alkyl-N-carboxyethyl-N-hydroxyethylimidazolinium betaine, and/or N-tetradecyl-N,N-betaine type amphoteric surfactant (for example, trade name AMOGEN K, manufactured by DKS Co., Ltd.).

In a case where the above-mentioned surfactant is contained, the content thereof is preferably 0.01% to 10% by mass and more preferably 0.05% to 5% by mass with respect to the total solid content contained in the composition.

(Solvent)

A solvent can be added to the positive photosensitive resin layer from the viewpoint of the workability in a case of forming the resin layer.

Specific examples of the solvent include ethylene dichloride, cyclohexanone, methyl ethyl ketone, methanol, ethanol, propanol, ethylene glycol monomethyl ether, 1-methoxy-2-propanol, 2-methoxyethyl acetate, 1-methoxy-2-propyl acetate, dimethoxyethane, methyl lactate, ethyl lactate, N,N-dimethylacetamide, N,N-dimethylformamide, tetramethylurea, N-methylpyrrolidone, dimethyl sulfoxide, sulfolane, y-butyrolactone, toluene, and water, in which these solvent compounds may be used alone or in combination of two or more thereof.

[o-Naphthoquinonediazide Compound]

The o-naphthoquinonediazide compound used in the present invention is preferably an ester of 1,2-diazonaphthoquinone sulfonic acid chloride with a pyrogallol-acetone resin described in JP1968-028403B (JP-S43-028403B). Other suitable orthoquinonediazide compounds include an ester of 1,2-diazonaphthoquinone sulfonic acid chloride with a phenol formaldehyde resin described in U.S. Pat. Nos. 3,046,120A and 3,188,210A. Other useful o-naphthoquinonediazide compounds have been reported in many patents and are known. For example, mention may be made of those described in JP1972-005303A (JP-S47-005303A), JP1973-063802A (JP-S48-063802A), JP1973-063803A (JP-S48-063803A), JP1973-096575A (JP-S48-096575A), JP1974-038701A (JP-S49-038701A), JP1973-013354A (JP-S48-013354A), JP1962-018015B (JP-S37-018015B), JP1966-011222A (JP-S41-011222A), JP1970-009610A (JP-S45-009610A), JP1974-017481A (JP-S49-017481A), U.S. Pat. Nos. 2,797,213A, 3,454,400A, 3,544,323A, 3,573,917A, 3,674,495A, 3,785,825A, GB1227602A, GB1251345A, GB1267005A, GB1329888A, GB1330932A, and DE854890A.

A particularly preferred o-naphthoquinonediazide compound in the present invention is a compound obtained by reacting a polyhydroxy compound having a molecular weight of 1,000 or less with 1,2-diazonaphthoquinone sulfonic acid chloride. Specific examples of such a compound include those described in JP1976-139402A (JP-S51-139402A), JP1983-150948A (JP-S58-150948A), JP1983-203434A (JP-558-203434A), JP1984-165053A (JP-559-165053A), JP1985-121445A (JP-S60-121445A), JP1985-134235A (JP-560-134235A), JP1985-163043A (JP-S60-163043A), JP1986-118744A (JP-561-118744A), JP1987-010645A (JP-562-010645A), JP1987-010646A (JP-S62-010646A), JP1987-153950A (JP-S62-153950A), JP1987-178562A (JP-S62-178562A), JP1989-076047A (JP-H01-076047A), U.S. Pat. Nos. 3,102,809A, 3,126,281A, 3,130,047A, 3,148,983A, 3,184,310A, 3,188,210A, and 4,639,406A.

In a case of synthesizing these o-naphthoquinonediazide compounds, it is preferable to react 0.2 to 1.2 equivalents of 1,2-diazonaphthoquinone sulfonic acid chloride with respect to the hydroxyl group of the polyhydroxy compound, and it is more preferable to react 0.3 to 1.0 equivalent of 1,2-diazonaphthoquinone sulfonic acid chloride with respect to the hydroxyl group of the polyhydroxy compound. The resulting o-naphthoquinonediazide compound is a mixture of compounds having various positions and introduced amounts of 1,2-diazonaphthoquinone sulfonic acid ester groups, but the proportion of the compound in which all of the hydroxyl groups are converted into 1,2-diazonaphthoquinone sulfonic acid ester in the mixture (the content of the completely esterified compound) is preferably 5 mol % or more and more preferably 20 to 99 mol %. The amount of the o-naphthoquinonediazide compound in the positive photosensitive resin layer is 5% to 50% by weight and more preferably 15% to 40% by weight.

[Infrared Absorber]

The positive photosensitive resin layer preferably has an infrared absorber. As the infrared absorber, it is preferable to use an infrared absorber having an onium salt type structure, from the viewpoint that a positive action (development is suppressed in an unexposed portion and the development suppression is released or eliminated in an exposed portion) needs to be exerted between the constitutional units of the polymer. Specifically, a dye such as a cyanine coloring agent or a pyrylium salt can be suitably used.

Preferred examples of the above-mentioned dye include a cyanine dye described in JP1983-125246A (JP-S58-125246A), JP1984-084356A (JP-559-084356A), JP1984-202829A (JP-559-202829A), and JP1985-078787A (JP-560-078787A) and a cyanine dye described in GB434875A.

In addition, a near-infrared absorbing sensitizer described in U.S. Pat. No. 5,156,938A is suitably used, and further, a substituted aryl benzo(thio)pyrylium salt described in U.S. Pat. No. 3,881,924A; a trimethine thiapyrylium salt described in JP1982-142645A (JP-S57-142645A) (U.S. Pat. No. 4,327,169A); a pyrylium-based compound described in JP1983-181051A (JP-S58-181051A), JP1983-220143A (JP-558-220143A), JP1984-041363A (JP-559-041363A), JP1984-084248A (JP-S59-084248A), JP1984-084249A (JP-559-084249A), JP1984-146063A (JP-S59-146063A) and JP1984-146061A (JP-S59-146061A); a cyanine coloring agent described in JP1984-216146A (JP-559-216146A); a pentamethine thiopyrylium salt described in U.S. Pat. No. 4,283,475A; and a pyrylium compound disclosed in JP1993-135514B (JP-H05-135514B) and JP1993-019702B (JP-H05-019702B) are also preferably used.

In addition, a near-infrared absorbing dye described as Formula (II) in U.S. Pat. No. 4,756,993A can also be mentioned as the preferred dye.

Further, an anionic infrared absorber described in JP1998-079912 (JP-H10-079912) can also be suitably used. The anionic infrared absorber refers to a dye that has no cationic structure but has an anionic structure in a mother nucleus of a coloring agent that substantially absorbs infrared light.

Examples of the anionic infrared absorber include (c1) anionic metal complex, (c2) anionic carbon black, (c3) anionic phthalocyanine, and (c4) compound represented by General Formula (7). The counter cation of these anionic infrared absorbers is a monovalent cation or polyvalent cation containing a proton. In General Formula (7), Gₐ⁻ represents an anionic substituent, and G_{b} represents a neutral substituent. X^{m+} represents a 1- to m-valent cation containing a proton, and m represents an integer of 1 to 6.

[Gₐ⁻−M−G_{b}]ₘX^{m+} General Formula (7)

Here, the term “anionic metal complex” (c1) refers to a complex in which a center metal of a complex portion that substantially absorbs light and a ligand thereof is an anion as a whole.

Examples of the anionic carbon black (c2) include carbon blacks to which an anionic group such as a sulfonic acid, carboxylic acid, or phosphonic acid group is bonded as a substituent. Oxidation of carbon black with a predetermined acid, as well as other means as described in Carbon Black Handbook, 3rd ed. (edited by the Carbon Black Association, Apr. 5, 1995, published by Carbon Black Association) p. 12 may be adopted for introducing these groups into the carbon black.

An anionic infrared absorber obtained by ion-bonding an onium salt as a counter cation to an anionic group in this anionic carbon black is suitably used in the present invention, however, an adsorption product obtained by adsorption of an onium salt onto the carbon black is not included in the anionic infrared absorber of the present invention. Moreover, the effect of the present invention cannot be obtained with a simple adsorption product.

The term “anionic phthalocyanine” (c3) refers to a compound in which the anion group listed in the description of (c2) above is bonded as a substituent to a phthalocyanine skeleton to form an anion as a whole.

Next, the compound represented by General Formula (7) (c4) will be described in detail. In General Formula (7), M represents a conjugated chain, and the conjugated chain M may have a substituent or a ring structure. The conjugated chain M can be represented by the following formula. In the following formula, R¹, R², and R³ each independently represent a hydrogen atom, a halogen atom, a cyano group, an alkyl group, an aryl group, an alkenyl group, an alkynyl group, a carbonyl group, a thio group, a sulfonyl group, a sulfinyl group, an oxy group, or an amino group, in which these groups may be linked to each other to form a ring structure. n represents an integer of 1 to 8.

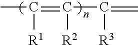

Among the anionic infrared absorbers represented by General Formula (7), A-1 to A-19 described below are preferably used.

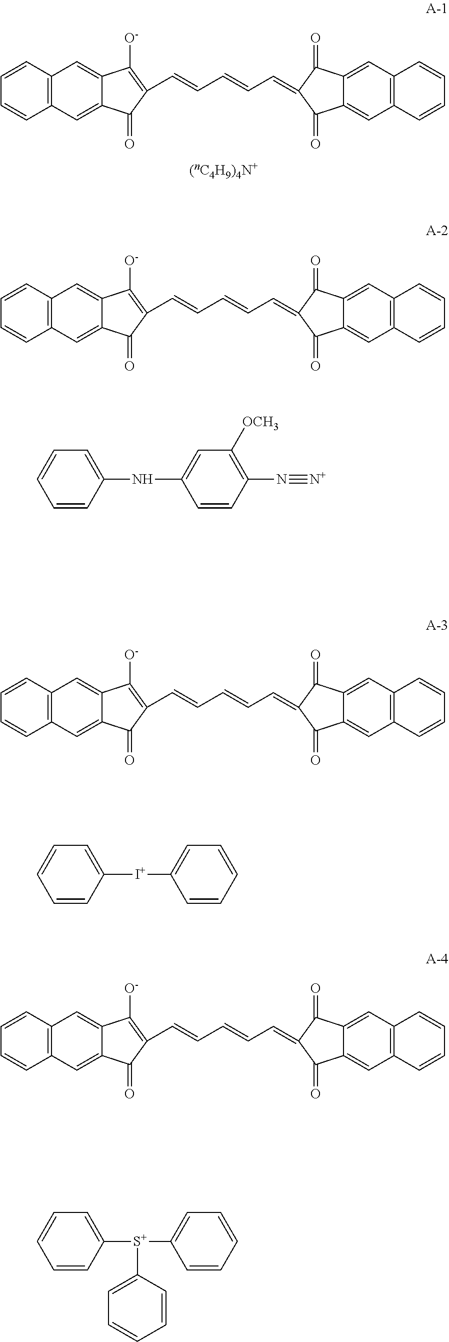

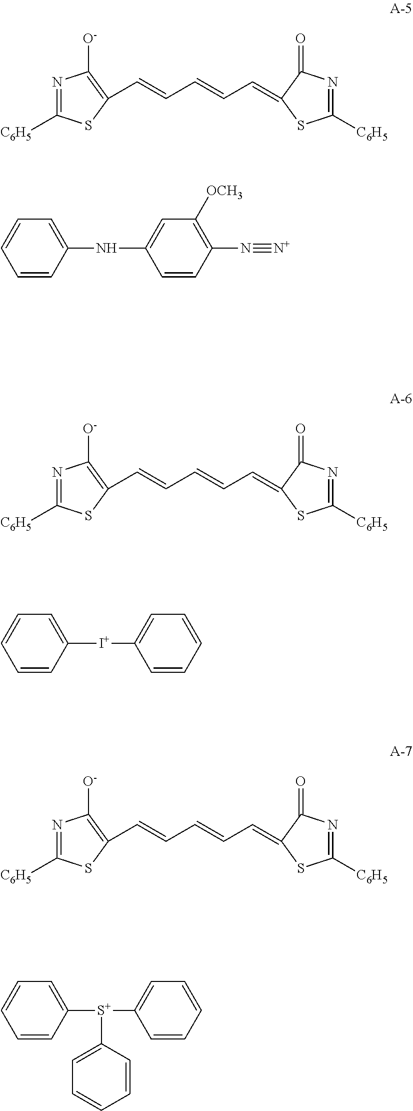

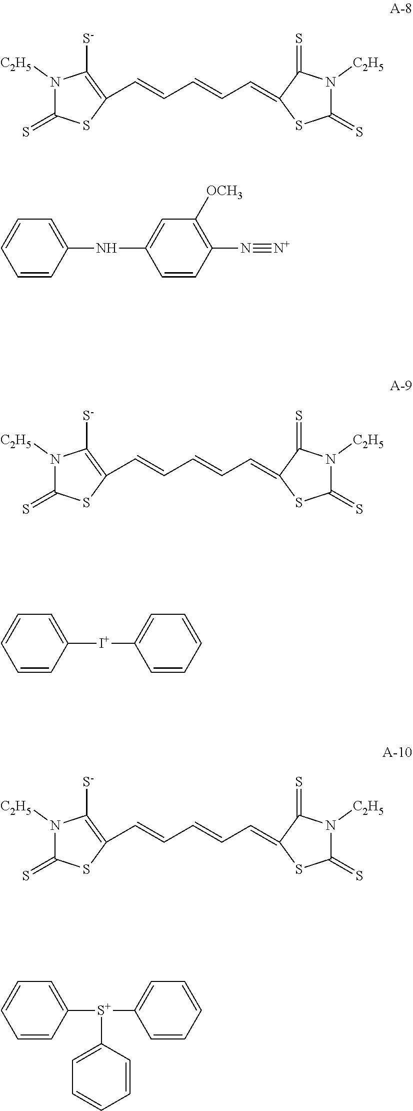

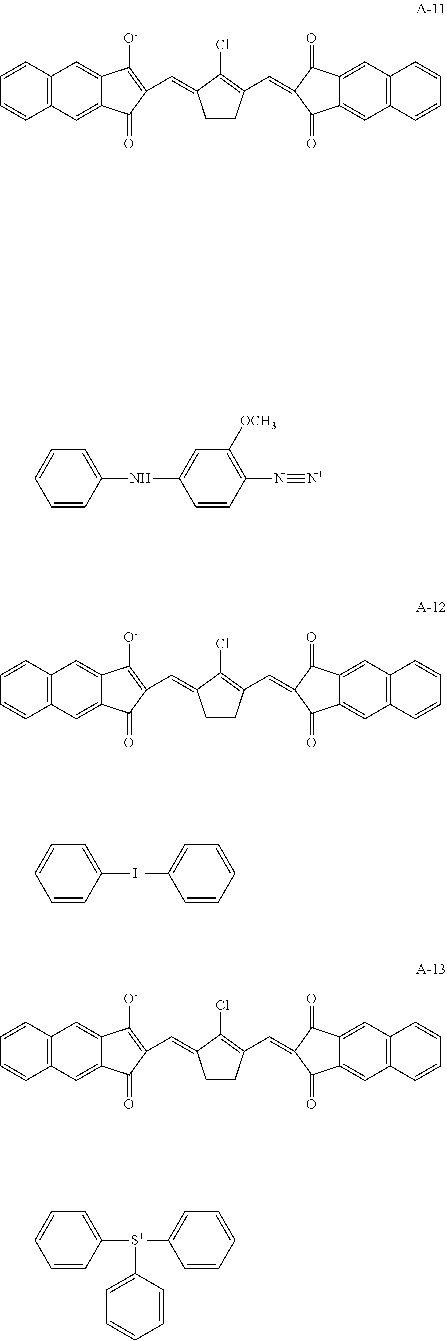

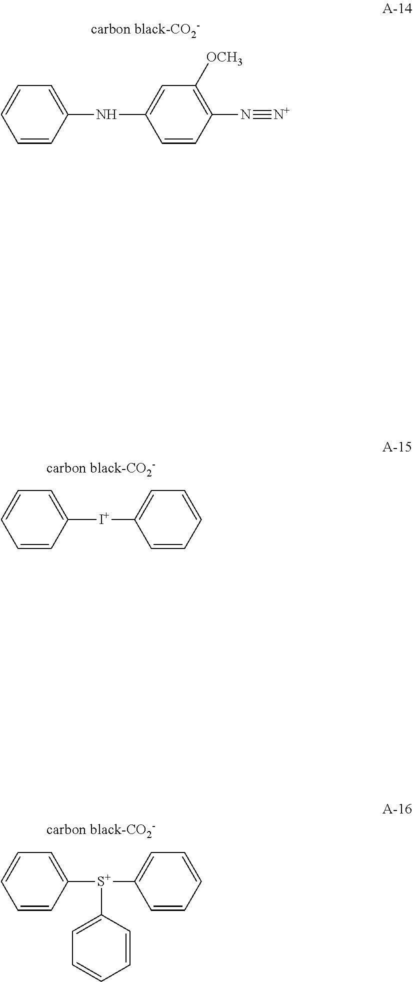

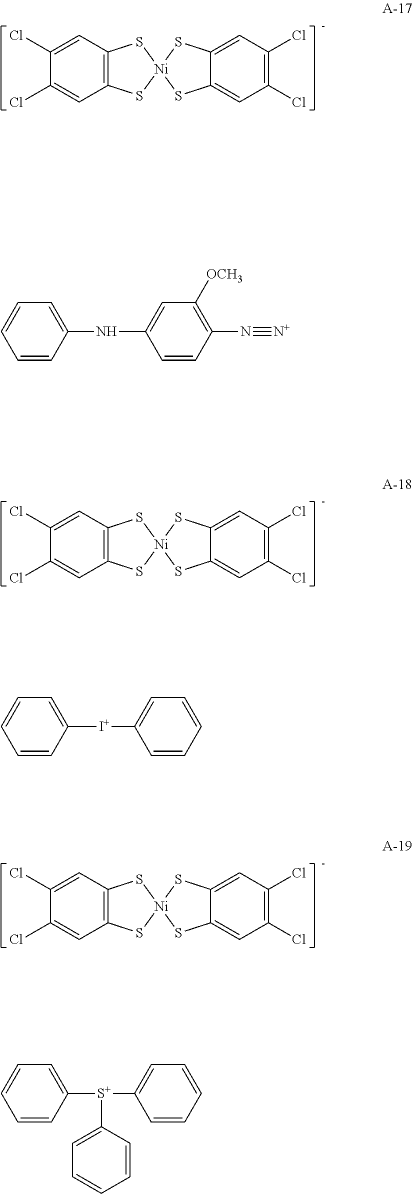

These dyes can be added in an amount of 0.01% to 50% by weight, preferably 0.1% to 10% by weight, and particularly preferably 0.5% to 10% by weight, with respect to the total solid content of the positive photosensitive resin layer. In a case where the amount of the dye added is less than 0.01% by weight, the sensitivity becomes low, whereas, in a case where the amount of the dye added is more than 50% by weight, the tint becomes poor.

[Coloring Material]

The positive photosensitive resin layer can also contain other dyes, pigments, and the like for the purpose of further improving the sensitivity and the development latitude.

The dyes which can be used include commercially available dyes and known dyes described in technical literatures such as “Handbook of Dyes” (edited by the Society of Synthetic Organic Chemistry, Japan, 1970). Specific examples thereof include dyes such as an azo dye, a metal complex salt azo dye, a pyrazolone azo dye, a naphthoquinone dye, an anthraquinone dye, a phthalocyanine dye, a carbonium dye, a quinone imine dye, a methine dye, a squalylium coloring agent, and a metal thiolate complex.

The pigments which can be used include commercially available pigments and pigments described in technical literatures, such as the Color Index (C. I.) Handbook, “Latest Handbook of Pigments” (Japan Association Of Pigment Technology, 1977), “Latest Pigment Applied Technology” (CMC Publishing Co., Ltd., 1986), and “Printing Ink Technology” (CMC Publishing Co., Ltd., 1984).

For example, the types of pigment include a black pigment, a yellow pigment, an orange pigment, a brown pigment, a red pigment, a violet pigment, a blue pigment, a green pigment, a fluorescent pigment, a metal powder pigment, and a polymer-bound coloring agent. Specific examples thereof which can be used include an insoluble azo pigment, an azo lake pigment, a condensed azo pigment, a chelated azo pigment, a phthalocyanine-based pigment, an anthraquinone-based pigment, a perylene- or perinone-based pigment, a thioindigo-based pigment, a quinacridone-based pigment, a dioxazine-based pigment, an isoindolinone-based pigment, a quinophthalone-based pigment, a dyed lake pigment, an azine pigment, a nitroso pigment, a nitro pigment, a natural pigment, a fluorescent pigment, an inorganic pigment, and a carbon black. Among these pigments, carbon black is preferable.

These pigments may be used with or without a surface treatment. Examples of surface treatment methods which can be considered include a method of applying a surface coat of resin or wax, a method of applying a surfactant, and a method of binding a reactive substance (for example, a silane coupling agent, an epoxy compound, or a polyisocyanate) to the pigment surface. These surface treatment methods are described in “Properties and Applications of Metallic Soap” (published by Saiwai Shobo), “Printing Ink Technology” (CMC Publishing Co., Ltd., 1984), and “Latest Pigment Applied Technology” (CMC Publishing Co., Ltd., 1986)

The particle size of the pigment is preferably in the range of 0.01 μm to 10 μm, more preferably in the range of 0.05 μm to 1 μm, and particularly preferably in the range of 0.1 μm to 1 μm. In a case where the particle size of the pigment is less than 0.01 μm, it is not preferable in terms of the stability of a dispersed substance in an image recording layer coating liquid, and in a case where the particle size of the pigment is more than 10 μm, it is not preferable in terms of the uniformity of an image recording layer.

As a method of dispersing the pigment, a known dispersion technique used in the production of an ink, toner, or the like can be employed. Examples of the dispersing machine include an ultrasonic disperser, a sand mill, an attritor, a pearl mill, a super mill, a ball mill, an impeller, a disperser, a KD mill, a colloid mill, a dynatron, a three-roll mill, and a pressure kneader. The details thereof are described in “Latest Pigment Applied Technology” (CMC Publishing Co., Ltd., 1986).

The amount of these dyes or pigments added with respect to the total solid content of the positive photosensitive resin layer is preferably 0.01% to 50% by weight and more preferably 0.1% to 10% by weight. In a case of a dye, it can be added to the positive photosensitive resin layer particularly preferably in the range of 0.5% to 10% by weight, and in a case of a pigment, it can be added to the positive photosensitive resin layer particularly preferably in the range of 1.0% to 10% by weight. In a case where the amount of the pigment or dye added is less than 0.01% by weight, the sensitivity becomes low, whereas, in a case where the amount of the pigment or dye added is more than 50% by weight, the tint becomes poor.

These dyes or pigments may be added to the same layer together with other components, or another layer may be provided to which the dyes or pigments are added. In addition, among the above-mentioned dyes or pigments, those that absorb infrared light or near-infrared light are particularly preferable. In addition, the dyes and pigments may be used in combinations of two or more thereof.

[Resin Layer]

The resin layer is not particularly limited as long as it is a layer formed of a resin material having transparency, and examples of the resin material include polyester and polyolefin.

Specific examples of the polyester include polyethylene terephthalate (PET) and polyethylene naphthalate.

Specific examples of other resin materials include polyamide, polyether, polystyrene, polyesteramide, polycarbonate, polyphenylene sulfide, polyetherester, polyvinyl chloride, polyacrylate, and polymethacrylate.

Here, the phrase “having transparency” indicates that the transmittance of visible light is 60% or more, preferably 80% or more, and particularly preferably 90% or more.

<Thickness>

The above-mentioned resin layer has an average thickness of preferably 12 to 100 μm, more preferably 25 to 100 μm, and still more preferably 50 to 100 μm, from the viewpoint of handleability and workability. Note that the average thickness of the resin layer is an average value of thicknesses measured at any five points using a contact type film thickness meter (digital electronic micrometer).

<Light Transmittance>

The light transmittance of the composite is preferably 0.1% to 90%. The light transmittance can be adjusted by the average opening ratio.

The light transmittance is an average value of the transmittance of light in a wavelength range of 200 nm to 900 nm, and is a transmittance measured according to Japanese Industrial Standard (JIS) K 7361.

Hereinafter, a method for producing a composite will be described.

[Method for Producing Composite]

The method for producing a composite is not particularly limited and includes, for example, a film forming step of forming an aluminum hydroxide film on at least one surface of a metal foil; a through-hole forming step of forming a through-hole by carrying out a through-hole forming treatment after the film forming step; a film removing step of removing the aluminum hydroxide film after the through-hole forming step; and a positive photosensitive resin layer forming step of forming a positive photosensitive resin layer on at least one surface of the metal foil having through-holes after the film removing step.

The method for producing a composite includes a resin layer forming step of forming a resin layer on one surface of a metal foil; a film forming step of forming an aluminum hydroxide film on the surface of the metal foil on which the resin layer is not provided, after the resin layer forming step; a through-hole forming step of forming a through-hole by carrying out a through-hole forming treatment after the film forming step; a film removing step of removing the aluminum hydroxide film after the through-hole forming step; and a positive photosensitive resin layer forming step of forming a positive photosensitive resin layer on the surface of the metal foil on which the resin layer is not provided.

Hereinafter, the method for producing a composite will be described with reference to the drawings, and then each step will be described in detail.

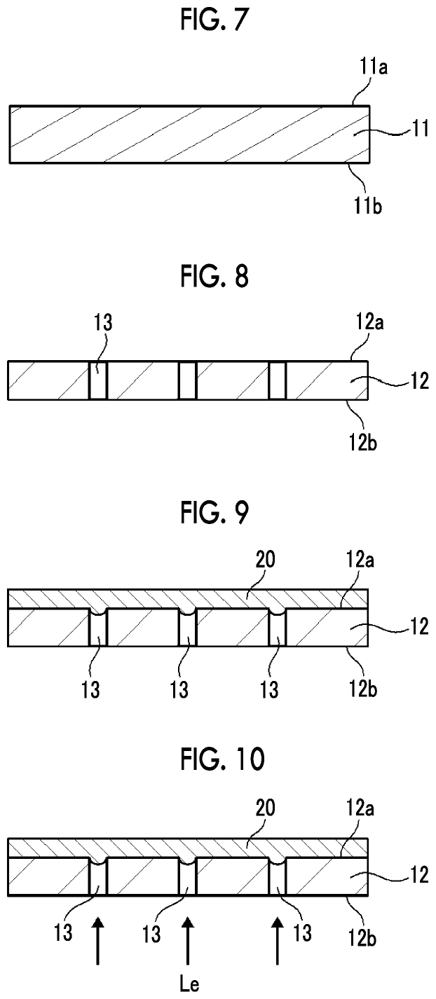

FIGS. 7 to 11 are schematic cross-sectional views showing a first example of a method for producing a composite according to the embodiment of the present invention in the order of steps. The first example of the method for producing a composite is an example of the method for producing the composite 10 shown in FIGS. 1 and 2. In FIGS. 7 to 11, the same components as those of the composite 10 shown in FIGS. 1 and 2 are denoted by the same reference numerals, and detailed description thereof will be omitted.

First, a metal substrate 11 (see FIG. 7) serving as the metal foil 12 (see FIG. 2) is prepared. The metal substrate 11 is made of aluminum, for example. Hereinafter, the metal substrate 11 made of aluminum will be described as an example.

Next, a film forming treatment is carried out on both surfaces 11a and 11b of the metal substrate 11 to form an aluminum hydroxide film (not shown). The step of forming the aluminum hydroxide film is referred to as a film forming step.

After the film forming step, for example, a through-hole is formed by carrying out an electrolytic dissolution treatment. The step of forming a through-hole is referred to as a through-hole forming step. After the through-hole forming step, the aluminum hydroxide film is removed. The step of removing the aluminum hydroxide film is referred to as a film removing step.

Through the foregoing steps, the metal foil 12 having the through-holes 13 is obtained as shown in FIG. 8.

Next, a positive photosensitive resin composition to be the positive photosensitive resin layer 14 (see FIG. 2) is applied onto the surface 12a of the metal foil 12 to form a positive photosensitive resin film 20, as shown in FIG. 9.

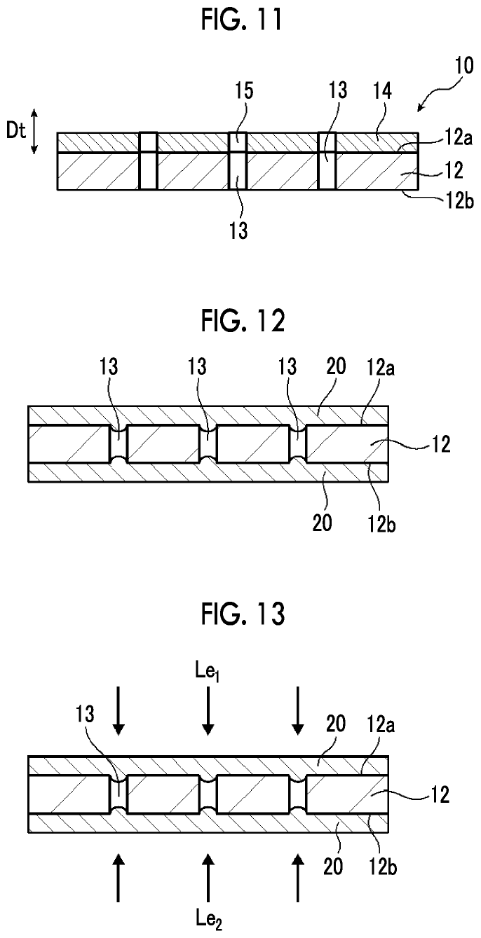

Next, as shown in FIG. 10, the exposure light Le is irradiated from the surface 12b side of the metal foil 12, and the exposure light Le transmitted through the through-holes 13 is irradiated to the positive photosensitive resin film 20 to be exposed, using the metal foil 12 as a mask. Next, the positive photosensitive resin film 20 is developed. As shown in FIG. 11, the development results in the formation of the positive photosensitive resin layer 14 having the through-holes 15 formed, whose positions coincide with the positions of the through-holes 13 of the metal foil 12. As a result, the composite 10 in which the positive photosensitive resin layer 14 is formed on one surface 12a of the metal foil 12 is obtained. The step of forming the positive photosensitive resin layer 14 is referred to as a positive photosensitive resin layer forming step.

FIGS. 12 to 14 are schematic cross-sectional views showing a second example of a method for producing a composite according to the embodiment of the present invention in the order of steps. The second example of the method for producing a composite is an example of the method for producing the composite 10 shown in FIG. 5. In FIGS. 12 to 14, the same components as those of the configuration shown in FIGS. 7 to 11 are denoted by the same reference numerals, and detailed description thereof will be omitted.

In the second example, the steps up to the step of obtaining the metal foil 12 in which the through-holes 13 are formed, which is shown in FIG. 8, are the same as those in the first example of the above-mentioned method for producing a composite.

A positive photosensitive resin composition to be the positive photosensitive resin layer 14 (see FIG. 2) is applied onto both surfaces of the metal foil 12 in which the through-holes 13 are formed, which is shown in FIG. 8, to form positive photosensitive resin films 20, as shown in FIG. 12. In this case, one surface 12a of the metal foil 12 and the other surface 12b of the metal foil 12 have different exposure wavelengths. For example, one positive photosensitive resin film 20 is exposed to infrared light, and the other positive photosensitive resin film 20 is exposed to UV light. Thereby, each of the positive photosensitive resin films 20 can be exposed in one step.

Next, as shown in FIG. 13, the exposure light Le₁ is irradiated from one surface 12a side, and the exposure light Le₂ is irradiated from the other surface 12b side, and the exposure is carried out with the respective exposure lights Le₁ and Le₂ that have passed through the through-holes 13 using the metal foil 12 as a mask.

The exposure light Le₁ is light having a wavelength for exposing the positive photosensitive resin film 20 on the other surface 12b side. The exposure light Le₂ is light having a wavelength for exposing the positive photosensitive resin film 20 on the one surface 12a side.

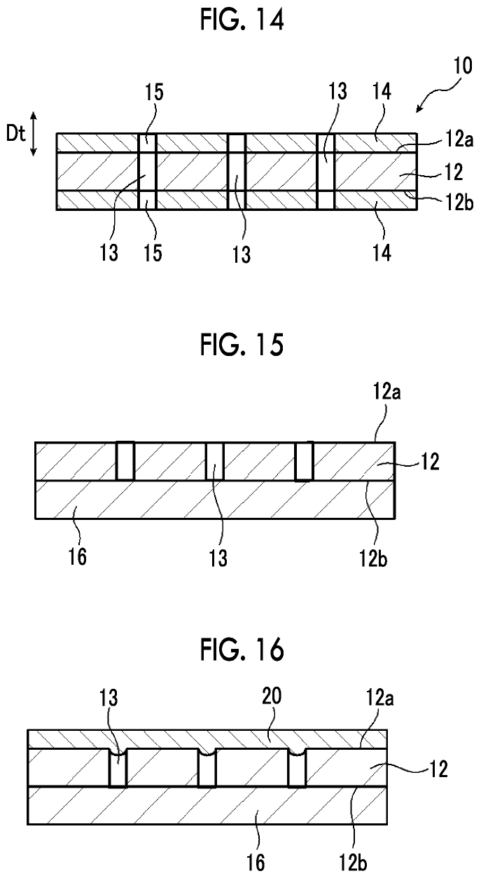

Next, each of the positive photosensitive resin films 20 is developed. As shown in FIG. 14, the development results in the formation of the positive photosensitive resin layer 14 having the through-holes 15 formed in a region of the positive photosensitive resin film 20 whose positions coincide with the positions of the through-holes 13 of the metal foil 12. As a result, the composite 10 in which the positive photosensitive resin layer 14 is formed on each of one surface 12a and the other surface 12b of the metal foil 12 is obtained.

FIGS. 15 to 18 are schematic cross-sectional views showing a third example of a method for producing a composite according to the embodiment of the present invention in the order of steps. The third example of the method for producing a composite is an example of the method for producing the composite 10 shown in FIG. 6. In FIGS. 15 to 18, the same components as those of the configuration shown in FIGS. 7 to 11 are denoted by the same reference numerals, and detailed description thereof will be omitted.

In the third example, the steps up to the step of obtaining the metal foil 12 in which the through-holes 13 are formed, which is shown in FIG. 8, are the same as those in the first example of the above-mentioned method for producing a composite.

As shown in FIG. 15, the resin layer 16 is formed on the surface 12b of the metal foil 12 using PET. The step of forming the resin layer 16 is referred to as a resin layer forming step.

Next, a positive photosensitive resin composition to be the positive photosensitive resin layer 14 (see FIG. 2) is applied onto the surface 12a of the metal foil 12 to form the positive photosensitive resin film 20, as shown in FIG. 16.

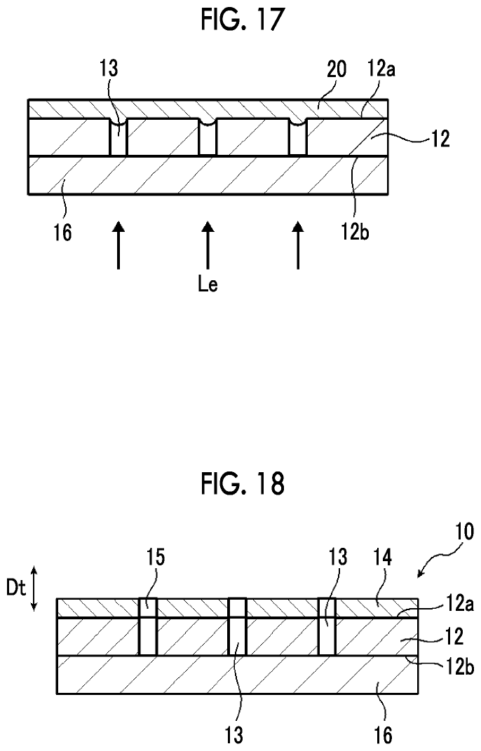

Next, as shown in FIG. 17, the exposure light Le is irradiated from the surface 12b side of the metal foil 12 on which the resin layer 16 is formed, and the exposure light Le transmitted through the through-holes 13 is irradiated to the positive photosensitive resin film 20 to be exposed, using the metal foil 12 as a mask. Next, the positive photosensitive resin film 20 is developed. As shown in FIG. 18, the development results in the formation of the_positive photosensitive resin layer 14 having the through-holes 15 formed in a region of the positive photosensitive resin film 20 whose positions coincide with the positions of the through-holes 13 of the metal foil 12. As a result, the_composite 10 in which the positive photosensitive resin layer 14 is formed on one surface 12a of the metal foil 12 and the resin layer 16 is formed on the other surface 12b of the metal foil 12 is obtained.

Hereinafter, each step of the method for producing a composite will be described in more detail.

[Film Forming Step]

The film forming step in the method for producing a composite is a step of carrying out a film forming treatment on a surface of a metal foil to form an aluminum hydroxide film.

<Film Forming Treatment>

The above-mentioned film forming treatment is not particularly limited, and for example, the same treatment as the conventionally known aluminum hydroxide film forming treatment can be carried out.

For example, the conditions and apparatuses described in paragraphs [0013] to [0026] of JP2011-201123A can be appropriately employed for the film forming treatment.

The conditions for the film forming treatment vary depending on the electrolytic solution used and thus cannot be unconditionally determined; but in general, the conditions for the film forming treatment are suitably an electrolytic solution concentration of 1% to 80% by mass, a liquid temperature of 5° C. to 70° C., a current density of 0.5 to 60 A/dm², a voltage of 1 to 100 V, and an electrolysis time of 1 second to 20 minutes, which are adjusted so as to obtain a desired film amount.

It is preferable to carry out an electrochemical treatment using nitric acid, hydrochloric acid, sulfuric acid, phosphoric acid, oxalic acid, or a mixed acid of two or more of these acids in the electrolytic solution.

In a case where the electrochemical treatment is carried out in an electrolytic solution containing nitric acid or hydrochloric acid, a direct current may be applied between a metal foil and a counter electrode, or an alternating current may be applied therebetween. In a case where a direct current is applied to the metal foil, the current density is preferably 1 to 60 A/dm² and more preferably 5 to 50 A/dm². In a case where the electrochemical treatment is continuously carried out, it is preferably carried out by a liquid power supply method in which power is supplied to the metal foil through an electrolytic solution.

In the present invention, the amount of the aluminum hydroxide film formed by the film forming treatment is preferably 0.05 to 50 g/m² and more preferably 0.1 to 10 g/m².

[Through-Hole Forming Step]

The through-hole forming step is a step of forming a through-hole by carrying out an electrolytic dissolution treatment after the film forming step.

<Electrolytic Dissolution Treatment>

The above-mentioned electrolytic dissolution treatment is not particularly limited and is carried out using a direct current or an alternating current. An acidic solution can be used for the electrolytic solution. Above all, it is preferable to carry out the electrochemical treatment using at least one acid of nitric acid or hydrochloric acid, and it is more preferable to carry out the electrochemical treatment using a mixed acid obtained by adding at least one or more acids of sulfuric acid, phosphoric acid, and oxalic acid to these acids.

In the present invention, as the acidic solution which is an electrolytic solution, the electrolytic solutions described in U.S. Pat. Nos. 4,671,859A, 4,661,219A, 4,618,405A, 4,600,482A, 4,566,960A, 4,566,958A, 4,566,959A, 4,416,972A, 4,374,710A, 4,336,113A, 4,184,932A, and the like can also be used in addition to the above-mentioned acids.

The concentration of the acidic solution is preferably 0.1% to 2.5% by mass and particularly preferably 0.2% to 2.0% by mass. The liquid temperature of the acidic solution is preferably 20° C. to 80° C. and more preferably 30° C. to 60° C.

In addition, an aqueous solution containing the above-mentioned acids as a main component can be used by adding at least one of a nitric acid compound having a nitric acid ion (such as aluminum nitrate, sodium nitrate, or ammonium nitrate), a hydrochloric acid compound having a hydrochloric acid ion (such as aluminum chloride, sodium chloride, or ammonium chloride), or sulfuric acid compound having a sulfuric acid ion (such as aluminum sulfate, sodium sulfate, or ammonium sulfate) in the range of from 1 g/L to saturation to the aqueous solution of an acid having a concentration of 1 to 100 g/L.

Here, the phrase “containing . . . as a main component” means that the main component in the aqueous solution is contained in an amount of 30% by mass or more and preferably 50% by mass or more with respect to the total components added to the aqueous solution. Hereinafter, the same applies to other components.

In addition, a metal contained in an aluminum alloy, such as iron, copper, manganese, nickel, titanium, magnesium, or silica, may be dissolved in the aqueous solution containing the above-mentioned acids as a main component. It is preferable to use a liquid in which aluminum chloride, aluminum nitrate, aluminum sulfate, or the like is added to an aqueous solution having an acid concentration of 0.1% to 2% by mass such that aluminum ions are 1 to 100 g/L.

A direct current is mainly used in the electrochemical dissolution treatment, but in a case where an alternating current is used, the alternating current power wave is not particularly limited, and a sine wave, a rectangular wave, a trapezoidal wave, a triangular wave, or the like is used. Among these, a rectangular wave or a trapezoidal wave is preferable, and a trapezoidal wave is particularly preferable.

(Nitric Acid Electrolysis)

In the present invention, through-holes having an average opening diameter of 0.1 μm or more and less than 100 μm can be easily formed by an electrochemical dissolution treatment using an electrolytic solution containing nitric acid as a main component (hereinafter, also referred to simply as “nitric acid dissolution treatment”).

Here, the nitric acid dissolution treatment is preferably an electrolytic treatment carried out using a direct current under conditions that the average current density is 5 A/dm² or more and the electric quantity is 50 C/dm² or more because it is easy to control the dissolution point of through-hole formation. The average current density is preferably 100 A/dm² or less, and the electric quantity is preferably 10,000 C/dm² or less.

In addition, the concentration and temperature of the electrolytic solution in nitric acid electrolysis are not particularly limited. The electrolysis can be carried out at 30° C. to 60° C. using a nitric acid electrolytic solution having a high concentration, for example, a nitric acid concentration of 15% to 35% by mass, or the electrolysis can be carried out at a high temperature, for example, 80° C. or higher using a nitric acid electrolytic solution having a nitric acid concentration of 0.7% to 2% by mass.

In addition, the electrolysis can be carried out using an electrolytic solution obtained by mixing at least one of sulfuric acid, oxalic acid, or phosphoric acid having a concentration of 0.1% to 50% by mass with the above-mentioned nitric acid electrolytic solution.

(Hydrochloric Acid Electrolysis)

In the present invention, through-holes having an average opening diameter of 1 μm or more and less than 100 μm can also be easily formed by an electrochemical dissolution treatment using an electrolytic solution containing hydrochloric acid as a main component (hereinafter, also referred to simply as “hydrochloric acid dissolution treatment”).

Here, the hydrochloric acid dissolution treatment is preferably an electrolytic treatment carried out using a direct current under conditions that the average current density is 5 A/dm² or more and the electric quantity is 50 C/dm² or more because it is easy to control the dissolution point of through-hole formation. The average current density is preferably 100 A/dm² or less, and the electric quantity is preferably 10,000 C/dm² or less.

In addition, the concentration and temperature of the electrolytic solution in hydrochloric acid electrolysis are not particularly limited. The electrolysis can be carried out at 30° C. to 60° C. using a hydrochloric acid electrolytic solution having a high concentration, for example, a hydrochloric acid concentration of 10% to 35% by mass, or the electrolysis can be carried out at a high temperature, for example, 80° C. or higher using a hydrochloric acid electrolytic solution having a hydrochloric acid concentration of 0.7% to 2% by mass.

In addition, the electrolysis can be carried out using an electrolytic solution obtained by mixing at least one of sulfuric acid, oxalic acid, or phosphoric acid having a concentration of 0.1% to 50% by mass with the above-mentioned hydrochloric acid electrolytic solution.

[Film Removing Step]

The film removing step is a step of carrying out a chemical dissolution treatment to remove the aluminum hydroxide film.

The above-mentioned film removing step is capable of removing the aluminum hydroxide film by carrying out, for example, an acid etching treatment or alkaline etching treatment which will be described later.

<Acid Etching Treatment>

The above-mentioned dissolution treatment is a treatment for dissolving the aluminum hydroxide film using a solution that preferentially dissolves aluminum hydroxide over aluminum (hereinafter, referred to as “aluminum hydroxide-dissolving solution”).

Here, the aluminum hydroxide-dissolving solution is preferably, for example, an aqueous solution containing at least one selected from the group consisting of nitric acid, hydrochloric acid, sulfuric acid, phosphoric acid, oxalic acid, a chromium compound, a zirconium-based compound, a titanium-based compound, a lithium salt, a cerium salt, a magnesium salt, sodium silicofluoride, zinc fluoride, a manganese compound, a molybdenum compound, a magnesium compound, a barium compound, and elemental halogen.

Specifically, examples of the chromium compound include chromium (III) oxide and chromium (VI) anhydride.

Examples of the zirconium-based compound include zirconium ammonium fluoride, zirconium fluoride, and zirconium chloride.

Examples of the titanium compound include titanium oxide and titanium sulfide.

Examples of the lithium salt include lithium fluoride and lithium chloride.

Examples of the cerium salt include cerium fluoride and cerium chloride.

Examples of the magnesium salt include magnesium sulfide.

Examples of the manganese compound include sodium permanganate and calcium permanganate.

Examples of the molybdenum compound include sodium molybdate.

Examples of the magnesium compound include magnesium fluoride pentahydrate.

Examples of the barium compound include barium oxide, barium acetate, barium carbonate, barium chlorate, barium chloride, barium fluoride, barium iodide, barium lactate, barium oxalate, barium perchlorate, barium selenate, barium selenite, barium stearate, barium sulfite, barium titanate, barium hydroxide, barium nitrate, and hydrates thereof.

Among the barium compounds described above, barium oxide, barium acetate, and barium carbonate are preferable, and barium oxide is particularly preferable.

Examples of the elemental halogen include chlorine, fluorine, and bromine.

Above all, the above-mentioned aluminum hydroxide-dissolving solution is preferably an aqueous solution containing an acid. Examples of the acid include nitric acid, hydrochloric acid, sulfuric acid, phosphoric acid, and oxalic acid. The acid may be a mixture of two or more acids. Above all, it is preferable to use nitric acid as the acid.

The acid concentration is preferably 0.01 mol/L or more, more preferably 0.05 mol/L or more, and still more preferably 0.1 mol/L or more. The upper limit of the acid concentration is not particularly limit, but generally it is preferably 10 mol/L or less and more preferably 5 mol/L or less.

The dissolution treatment is carried out by bringing the metal foil on which the aluminum hydroxide film is formed into contact with the above-mentioned dissolution solution. The method of bringing the metal foil into contact with the dissolution solution is not particularly limited, and examples thereof include a dipping method and a spray method. Especially, a dipping method is preferable.

The dipping method is a treatment in which a metal foil on which an aluminum hydroxide film is formed is dipped in the above-mentioned dissolution solution. It is preferable to carry out the stirring during the dipping treatment, since the treatment without unevenness is carried out.

The dipping time is preferably 10 minutes or more, more preferably 1 hour or more, still more preferably 3 hours or more, and even still more preferably 5 hours or more.

<Alkaline Etching Treatment>

The alkaline etching treatment is a treatment in which a surface layer is dissolved by bringing the above-mentioned aluminum hydroxide film into contact with an alkaline solution.

Examples of the alkali used in the alkaline solution include a caustic alkali and an alkali metal salt. Specifically, examples of the caustic alkali include sodium hydroxide (caustic soda) and caustic potash. Examples of the alkali metal salt include alkali metal silicates such as sodium metasilicate, sodium silicate, potassium metasilicate, and potassium silicate; alkali metal carbonates such as sodium carbonate and potassium carbonate; alkali metal aluminates such as sodium aluminate and potassium aluminate; alkali metal aldonates such as sodium gluconate and potassium gluconate; and alkali metal hydrogen phosphates such as secondary sodium phosphate, secondary potassium phosphate, tertiary sodium phosphate, and tertiary potassium phosphate. Among these, a solution of a caustic alkali and a solution containing both a caustic alkali and an alkali metal aluminate are preferable from the viewpoint of high etching rate and low cost. In particular, an aqueous solution of sodium hydroxide is preferable.

The concentration of the alkaline solution is preferably 0.1% to 50% by mass and more preferably 0.2% to 10% by mass. In a case where aluminum ions are dissolved in the alkaline solution, the concentration of aluminum ions is preferably 0.01% to 10% by mass and more preferably 0.1% to 3% by mass. The temperature of the alkaline solution is preferably 10° C. to 90° C. The treatment time is preferably 1 to 120 seconds.

Examples of the method for bringing the aluminum hydroxide film into contact with the alkaline solution include a method in which a metal foil on which an aluminum hydroxide film is formed is passed through a tank containing an alkaline solution; a method in which a metal foil on which an aluminum hydroxide film is formed is dipped in a tank containing an alkaline solution; and a method in which an alkaline solution is sprayed onto a surface (aluminum hydroxide film) of a metal foil on which the aluminum hydroxide film is formed.

[Positive Photosensitive Resin Layer Forming Step]

The positive photosensitive resin layer forming step is carried out in such a manner that a composition of a positive photosensitive resin layer is applied onto a metal foil, exposure is carried out using the metal foil as a mask, and after the exposure, development is carried out to form a through-hole, thereby obtaining a positive photosensitive resin layer.

<Forming Method>

The above-mentioned method of forming a positive photosensitive resin layer is not particularly limited, but is preferably a method in which the composition of the positive photosensitive resin layer is applied onto the metal foil to form a positive photosensitive resin layer.

The method of applying the composition onto the metal foil is not particularly limited, and a method such as a bar coating method, a slit coating method, an ink jet method, a spray method, a roll coating method, a spin coating method, a casting coating method, a slit and spin method, or a transfer method can be used.

<Alkaline Aqueous Solution>

The alkaline aqueous solution is used for development. Specific examples of the alkaline aqueous solution include inorganic alkalis such as sodium hydroxide, potassium hydroxide, sodium carbonate, sodium silicate, sodium metasilicate, and aqueous ammonia; primary amines such as ethylamine and n-propylamine; secondary amines such as diethylamine and di-n-butylamine; tertiary amines such as triethylamine and methyldiethylamine; alcohol amines such as dimethylethanolamine and triethanolamine; quaternary ammonium salts such as tetramethylammonium hydroxide and tetraethylammonium hydroxide; and cyclic amines such as pyrrole and piperidine, in which these compounds may be used alone or in combination of two or more thereof.

In addition, an appropriate amount of alcohols or a surfactant can be added to the above-mentioned alkaline aqueous solution for use.

<Exposure Treatment>

In the exposure of the positive photosensitive resin layer, the positive photosensitive resin layer is exposed using a metal foil as a mask. As the exposure light, light having a wavelength at which the positive photosensitive resin layer has sensitivity is used. In the exposure, the exposure light is irradiated from the surface of the metal foil on which the positive photosensitive resin layer is not formed.

For example, ultraviolet (UV) light is used as the exposure light, and a known light source can be used.

<Development Treatment>

The development of the positive photosensitive resin layer is carried out by bringing the exposed positive photosensitive resin layer into contact with, for example, the above-mentioned alkaline aqueous solution.

The method of bringing them into contact with each other is not particularly limited, and examples thereof include a dipping method and a spray method. Especially, a dipping method is preferable.

The dipping time is preferably 5 seconds to 5 minutes and more preferably 10 seconds to 2 minutes.

In addition, the temperature of the alkaline aqueous solution in a case of dipping is preferably 25° C. to 60° C. and more preferably 30° C. to 50° C.

[Resin Layer Forming Step]

The resin layer forming step is a step of forming a resin layer on the surface of the metal foil on which the positive photosensitive resin layer is not formed, of the surfaces of the metal foil having through-holes.

The method for forming the resin layer is not particularly limited, and examples thereof include dry lamination, wet lamination, extrusion lamination, and inflation lamination.

Among these, as described above, a suitable aspect is an aspect in which the average thickness of the resin layer is 25 to 100 μm and an aspect in which the average thickness of the metal foil is 5 to 1000 μm, and thus a method of forming the resin layer by dry lamination is preferable.

With respect to the dry lamination, for example, the conditions and apparatus described in paragraphs [0067] to [0078] of JP2013-121673A can be appropriately employed.

[Method for Forming Through-Hole of Metal Foil]

The method for forming a through-hole of a metal foil is not limited to the above-mentioned method. Among the methods for producing a composite in a case where a metal foil other than an aluminum foil is used, the method for producing a through-hole of a metal foil will be described.

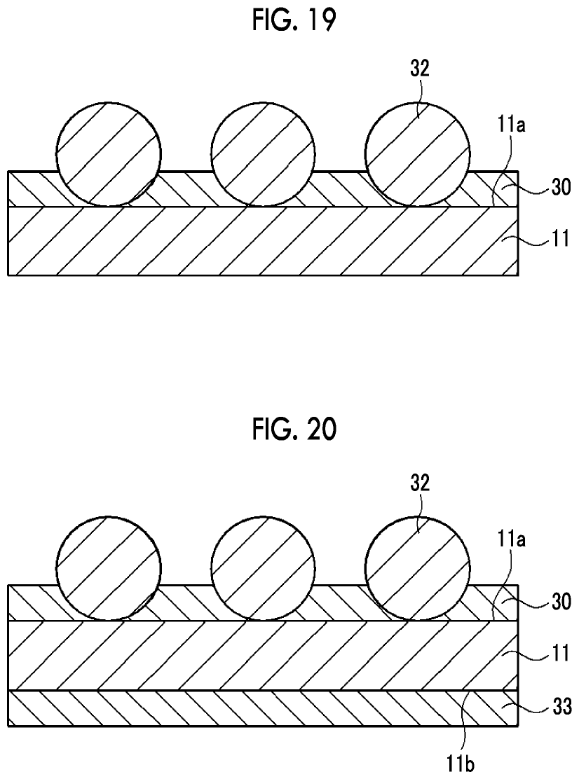

FIGS. 19 to 22 are schematic cross-sectional views showing another example of the method for producing a through-hole of the metal foil of the composite according to the embodiment of the present invention in the order of steps. In FIGS. 19 to 22, the same components as those of the composite 10 shown in FIGS. 1 and 2 are denoted by the same reference numerals, and detailed description thereof will be omitted.

First, by a resin layer forming step using a composition containing a plurality of metal particles and a polymer component, as shown in FIG. 19, a resin layer 30 in which a part of each of a plurality of metal particles 32 is embedded is formed on one surface 11a of the metal substrate 11.

By an optional protective layer forming step using a composition containing a polymer component, as shown in FIG. 20, it is preferable to form a protective layer 33 on the surface 11b of the metal substrate 11 opposite to the surface 11a on which the resin layer 30 is formed.

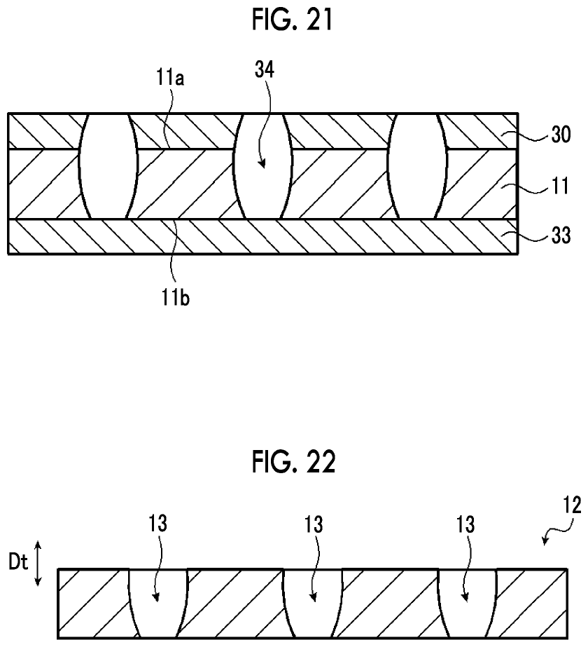

Next, by a through-hole forming step of bringing the metal substrate 11 having the resin layer 30 into contact with an etchant to dissolve the metal particles 32 and a part of the metal substrate 11, as shown in FIG. 21, through-holes 34 are formed in the resin layer 30 and the metal substrate 11.

The metal foil 12 having a plurality of through-holes 13 is formed by a resin layer removing step of removing the protective layer 33 and a protective layer removing step of removing the protective layer 33. Thus, the metal foil 12 in which the through-holes 13 are formed can be obtained.

[Step of Forming Resin Layer for Forming Through-Hole]

The step of forming a resin layer for forming a through-hole is a step of forming a resin layer in which a part of each of metal particles is embedded on one surface of the metal foil, using a composition containing a plurality of metal particles and a polymer component.

[Composition]

The composition used in the step of forming a resin layer for forming a through-hole is a composition containing at least a plurality of metal particles and a polymer component.

<Metal Particle>

The metal particle contained in the composition described above is not particularly limited as long as it is a particle containing a metal atom that dissolves in an etchant which will be described later for use in the through-hole forming step. The metal particle is preferably a particle made up of at least one of a metal or a metal compound and more preferably a particle made up of a metal.

Specific examples of the metal constituting the metal particle include aluminum, nickel, iron, copper, stainless steel, titanium, tantalum, molybdenum, niobium, zirconium, tungsten, beryllium, and an alloy thereof, in which these metals may be used alone or in combination of two or more thereof.

Of these metals, aluminum, nickel, and copper are preferable, and aluminum and copper are more preferable.

Examples of the metal compound constituting the metal particle include an oxide, a composite oxide, a hydroxide, a carbonate, a sulfate, a silicate, a phosphate, a nitride, a carbide, a sulfide, and a composite of at least two or more thereof. Specific examples of the metal compound constituting the metal particle include copper oxide, aluminum oxide, aluminum nitride, and aluminum borate.

From the viewpoint of recovering the etchant and recycling the dissolved metal, it is preferable that the metal particle and the above-mentioned metal foil contain the same metal atom.

The shape of the metal particle is not particularly limited, but is preferably spherical and more preferably closer to a true sphere.

In addition, the average particle size of the metal particles is preferably 1 to 10 μm and more preferably more than 2 μm and 6 μm or less, from the viewpoint of dispersibility in the composition.

Here, the average particle size of the metal particles refers to a cumulative 50% size of the particle size distribution measured by a laser diffraction/scattering type particle size analyzer (MICROTRACK MT3000, manufactured by Nikkiso Co., Ltd.).

In addition, the content of the metal particles is preferably 0.05% to 95% by mass, more preferably 1% to 50% by mass, and still more preferably 3% to 25% by mass with respect to the total solid content contained in the composition.

<Polymer Component>

The polymer component contained in the above-mentioned composition is not particularly limited, and a conventionally known polymer component can be used.

Specific examples of the polymer component include an epoxy-based resin, a silicone-based resin, an acrylic resin, a urethane-based resin, an ester-based resin, a urethane acrylate-based resin, a silicone acrylate-based resin, an epoxy acrylate-based resin, an ester acrylate-based resin, a polyamide-based resin, a polyimide-based resin, a polycarbonate-based resin, and a phenol-based resin, in which these resins may be used alone or in combination of two or more thereof.

Among them, the polymer component is preferably a resin material selected from the group consisting of a phenol-based resin, an acrylic resin, and a polyimide-based resin, from the viewpoint that excellent acid resistance is secured and even in a case where an acidic solution is used as an etchant which will be described later for use in the through-hole forming step, a desired through-hole is easily obtained.

From the viewpoint of easy removal in the resin layer removing step which will be described later, the polymer component contained in the composition is preferably a water-insoluble and alkaline water-soluble polymer (hereinafter, also referred to simply as “alkaline water-soluble polymer”), that is, a homopolymer containing an acidic group in a main chain or side chain of the polymer, a copolymer thereof, or a mixture thereof.

The alkaline water-soluble polymer is preferably a polymer having an acidic group in the main chain and/or side chain of the polymer, from the viewpoint of easier removal in the resin layer removing step which will be described later.

Specific examples of the acidic group include a phenol group (—Ar—OH), a sulfonamide group (—SO₂NH—R), a substituted sulfonamide-based acid group (hereinafter, referred to as “active imide group”) [—SO₂NHCOR, —SO₂NHSO₂R, or —CONHSO₂R], a carboxyl group (—CO₂H), a sulfo group (—SO₃H), and a phosphone group (—OPO₃H₂).

In addition, Ar represents a divalent aryl linking group which may have a substituent, and R represents a hydrocarbon group which may have a substituent.

Among the above-mentioned alkaline water-soluble polymers having an acidic group, an alkaline water-soluble polymer having a phenol group, a carboxyl group, a sulfonamide group, or an active imide group is preferable, and in particular, an alkaline water-soluble polymer having a phenol group or a carboxyl group is most preferable from the viewpoint of the balance between the strength of the resin layer to be formed and the removability thereof in the resin layer removing step which will be described later.

Examples of the above-mentioned alkaline water-soluble polymer having an acidic group include the following.

Examples of the alkaline water-soluble polymer having a phenol group include a novolak resin produced from one or more of phenols (such as phenol, o-cresol, m-cresol, p-cresol, and xylenol) and aldehydes (such as formaldehyde and paraformaldehyde), and a polycondensate of pyrogallol and acetone. Further, a copolymer obtained by copolymerizing a compound having a phenol group can also be mentioned. Examples of the compound having a phenol group include acrylamide, methacrylamide, acrylate, methacrylate, and hydroxystyrene which have a phenol group.

Specific examples of the compound having a phenol group include N-(2-hydroxyphenyl)acrylamide, N-(3-hydroxyphenyl)acrylamide, N-(4-hydroxyphenyl)acrylamide, N-(2-hydroxyphenyl)methacrylamide, N-(3-hydroxyphenyl)methacrylamide, N-(4-hydroxyphenyl)methacrylamide, o-hydroxyphenyl acrylate, m-hydroxyphenyl acrylate, p-hydroxyphenyl acrylate, o-hydroxyphenyl methacrylate, m-hydroxyphenyl methacrylate, p-hydroxyphenyl methacrylate, o-hydroxystyrene, m-hydroxystyrene, p-hydroxystyrene, 2-(2-hydroxyphenyl)ethyl acrylate, 2-(3-hydroxyphenyl)ethyl acrylate, 2-(4-hydroxyphenyl)ethyl acrylate, 2-(2-hydroxyphenyl)ethyl methacrylate, 2-(3-hydroxyphenyl)ethyl methacrylate, and 2-(4-hydroxyphenyl)ethyl methacrylate.

Among these, a novolak resin or a copolymer of hydroxystyrene is preferable. Examples of commercially available products of the copolymer of hydroxystyrene include MARUKA LYNCUR MH-2, MARUKA LYNCUR MS-4, MARUKA LYNCUR MS-2, and MARUKA LYNCUR MS-1 (all manufactured by Maruzen Petrochemical Co., Ltd.), and VP-8000 and VP-15000 (both manufactured by Nippon Soda Co., Ltd.).

The alkaline water-soluble polymer having a sulfonamide group may be, for example, a polymer made up of a minimum constitutional unit derived from a compound having a sulfonamide group, as a main structural component. Examples of the compound as described above include a compound having one or more sulfonamide groups in which at least one hydrogen atom is bonded to a nitrogen atom and one or more polymerizable unsaturated groups in a molecule thereof. Above all, a low molecular weight compound having an acryloyl group, an allyl group, or a vinyloxy group, and a substituted or monosubstituted aminosulfonyl group or a substituted sulfonylimino group in a molecule thereof is preferable.

In particular, m-aminosulfonylphenyl methacrylate, N-(p-aminosulfonylphenyl)methacrylamide, N-(p-aminosulfonylphenyl)acrylamide, or the like can be suitably used.

The alkaline water-soluble polymer having an active imide group may be, for example, a polymer made up of a minimum constitutional unit derived from a compound having an active imide group, as a main structural component. Examples of the compound as described above include a compound having one or more active imide groups represented by the following structural formula and one or more polymerizable unsaturated groups in a molecule thereof.

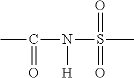

Specifically, N-(p-toluenesulfonyl)methacrylamide, N-(p-toluenesulfonyl)acrylamide, or the like can be suitably used.

The alkaline water-soluble polymer having a carboxyl group may be, for example, a polymer having a minimum constitutional unit derived from a compound having one or more carboxyl groups and one or more polymerizable unsaturated groups in a molecule thereof, as a main structural component. Specific examples thereof include polymers using unsaturated carboxylic compounds such as acrylic acid, methacrylic acid, maleic acid anhydride, and itaconic acid.

The alkaline water-soluble polymer having a sulfo group may be, for example, a polymer having a minimum constitutional unit derived from a compound having one or more sulfo groups and one or more polymerizable unsaturated groups in a molecule thereof, as a main constitutional unit.

The alkaline water-soluble polymer having a phosphone group may be, for example, a polymer having a minimum constitutional unit derived from a compound having one or more phosphone groups and one or more polymerizable unsaturated groups in a molecule thereof, as a main structural component.

The minimum constitutional unit having an acidic group, which constitutes the alkaline water-soluble polymer, is not particularly required to be only one type and alkaline water-soluble polymers obtained by copolymerizing two or more minimum constitutional units having the same acidic group or two or more minimum constitutional units having different acidic groups can also be used.

A conventionally known graft copolymerization method, block copolymerization method, random copolymerization method, or the like can be used as the copolymerization method.

The above-mentioned copolymer contains a compound having an acidic group to be copolymerized in an amount of preferably 10 mol % or more and more preferably 20 mol % or more in the copolymer.

In a case where a compound is copolymerized to form a copolymer, another compound not containing an acidic group can be used as the compound. Examples of the another compound not containing an acidic group include the compounds listed in the following (m1) to (m11).

(m1) acrylic esters and methacrylic esters having an aliphatic hydroxyl group such as 2-hydroxyethyl acrylate and 2-hydroxyethyl methacrylate.

(m2) alkyl acrylates such as methyl acrylate, ethyl acrylate, propyl acrylate, butyl acrylate, amyl acrylate, hexyl acrylate, octyl acrylate, benzyl acrylate, 2-chloroethyl acrylate, glycidyl acrylate, and N-dimethylaminoethyl acrylate.

(m3) alkyl methacrylates such as methyl methacrylate, ethyl methacrylate, propyl methacrylate, butyl methacrylate, amyl methacrylate, hexyl methacrylate, cyclohexyl methacrylate, benzyl methacrylate, 2-chloroethyl methacrylate, glycidyl methacrylate, and N-dimethylaminoethyl methacrylate.

(m4) acrylamides and methacrylamides such as acrylamide, methacrylamide, N-methylolacrylamide, N-ethylacrylamide, N-hexylmethacrylamide, N-cyclohexylacrylamide, N-hydroxyethylacrylamide, N-phenylacrylamide, N-nitrophenylacrylamide, and N-ethyl-N-phenylacrylamide.

(m5) vinyl ethers such as ethyl vinyl ether, 2-chloroethyl vinyl ether, hydroxyethyl vinyl ether, propyl vinyl ether, butyl vinyl ether, octyl vinyl ether, and phenyl vinyl ether.

(m6) vinyl esters such as vinyl acetate, vinyl chloroacetate, vinyl butyrate, and vinyl benzoate.

(m7) styrenes such as styrene, a-methylstyrene, methylstyrene, and chloromethyl styrene.

(m8) vinyl ketones such as methyl vinyl ketone, ethyl vinyl ketone, propyl vinyl ketone, and phenyl vinyl ketone.

(m9) olefins such as ethylene, propylene, isobutylene, butadiene, and isoprene.

(m10) N-vinylpyrrolidone, N-vinylcarbazole, 4-vinylpyridine, acrylonitrile, methacrylonitrile, and the like.

(m11) Maleimide, unsaturated amides such as N-acryloylacrylamide, N-acetylmethacrylamide, N-propionylmethacrylamide, and N-(p-chlorobenzoyl)methacrylamide.

The polymer component preferably has a weight-average molecular weight in the range of 1.0×10³ to 2.0×10⁵ and a number-average molecular weight in the range of 5.0×10² to 1.0×10⁵, regardless of a homopolymer or a copolymer. In addition, a polymer component having a polydispersity (weight-average molecular weight/number-average molecular weight) of 1.1 to 10 is preferable.

In a case where a copolymer is used as the polymer component, a blending weight ratio of a minimum constitutional unit that constitutes the main chain and/or side chain thereof and is derived from a compound having an acidic group to the other minimum constitutional unit that constitutes a part of the main chain and/or the side chain and does not contain an acidic group is preferably in the range of 50:50 to 5:95 and more preferably in the range of 40:60 to 10:90.

The above-mentioned polymer components may each be used alone or in combination of two or more thereof, and are preferably used in the range of 30% to 99% by mass, more preferably in the range of 40% to 95% by mass, and particularly preferably in the range of 50% to 90% by mass with respect to the total solid content contained in the composition.

In the present invention, regarding the metal particles and the polymer component described above, it is preferable that the specific gravity of the metal particles is larger than the specific gravity of the polymer component, from the viewpoint that the formation of a through-hole becomes easy in the through-hole forming step which will be described later. Specifically, it is preferable that the specific gravity of the metal particles is 1.5 or more, and the specific gravity of the polymer component is 0.9 or more and less than 1.5.

<Surfactant>

From the viewpoint of coating properties, a nonionic surfactant as described in JP1987-251740A (JP-562-251740A) and JP1991-208514A (JP-H03-208514A) or an amphoteric surfactant as described in JP1984-121044A (JP-S59-121044A) and JP1992-013149A (JP-H04-013149A) can be added to the above-mentioned composition.

Specific examples of the nonionic surfactant include sorbitan tristearate, sorbitan monopalmitate, sorbitan triolate, monoglyceride stearate, and polyoxyethylene nonyl phenyl ether.

Specific examples of the amphoteric surfactant include alkyl di(aminoethyl)glycine, alkyl polyaminoethyl glycine hydrochloride, 2-alkyl-N-carboxyethyl-N-hydroxyethylimidazolinium betaine, and N-tetradecyl-N,N-betaine type amphoteric surfactant (for example, trade name AMOGEN K, manufactured by DKS Co., Ltd.).

In a case where the above-mentioned surfactant is contained, the content thereof is preferably 0.01% to 10% by mass and more preferably 0.05% to 5% by mass with respect to the total solid content contained in the composition.

<Solvent>

A solvent can be added to the above-mentioned composition from the viewpoint of the workability in a case of forming the resin layer.

Specific examples of the solvent include ethylene dichloride, cyclohexanone, methyl ethyl ketone, methanol, ethanol, propanol, ethylene glycol monomethyl ether, 1-methoxy-2-propanol, 2-methoxyethyl acetate, 1-methoxy-2-propyl acetate, dimethoxyethane, methyl lactate, ethyl lactate, N,N-dimethylacetamide, N,N-dimethylformamide, tetramethylurea, N-methylpyrrolidone, dimethyl sulfoxide, sulfolane, y-butyrolactone, toluene, and water, in which these solvent compounds may be used alone or in combination of two or more thereof.

<Forming Method>

The method of forming a resin layer using the above-mentioned composition is not particularly limited, but is preferably a method of applying the composition onto a metal foil to form a resin layer.

The method of applying the composition onto the metal foil is not particularly limited, and a method such as a bar coating method, a slit coating method, an ink jet method, a spray method, a roll coating method, a spin coating method, a casting coating method, a slit and spin method, or a transfer method can be used.

In the present invention, it is preferable to form the resin layer so as to satisfy Expression (1) from the viewpoint that the formation of a through-hole is easy in the through-hole forming step which will be described later.

n<r (1)

Here, in Expression (1), n represents the thickness of the resin layer to be formed, r represents the average particle size of the metal particles contained in the composition, and the units of n and r both represent μm.

In addition, in the present invention, the thickness of the resin layer formed by the resin layer forming step is preferably 0.5 to 4 μm and more preferably 1 μm or more and 2 μm or less, from the viewpoint of the resistance to the etchant used in the through-hole forming step which will be described later or the workability in the resin layer removing step which will be described later.

Here, the average thickness of the resin layer refers to an average value of thicknesses at any five points measured in a case where the resin layer is cut using a microtome and the cross section is observed with an electron microscope.

[Protective Layer Forming Step]

Furthermore, from the viewpoint of the workability in the through-hole forming step which will be described later, it is preferable to include a protective layer forming step of forming a protective layer on the surface of the metal foil opposite to the surface on which the resin layer is formed, using a composition containing a polymer component, before the through-hole forming step.

Here, the polymer component may be the same as the polymer component contained in the composition which is used in the resin layer forming step described above. That is, the protective layer formed in an optional protective layer forming step is the same layer as the above-mentioned resin layer, except that the above-mentioned metal particles are not embedded therein. Also regarding the method of forming the protective layer, the protective layer can be formed in the same manner as in the above-mentioned resin layer, except that the above-mentioned metal particles are not used.

In a case where the protective layer forming step is included, the order of carrying out the protective layer forming step is not particularly limited as long as it is a step before the through-hole forming step, and the protective layer forming step may be a step which is carried out before, after, or simultaneously with the above-mentioned resin layer forming step.

[Through-Hole Forming Step]

The through-hole forming step included in the production method of the present invention is a step of bringing a metal foil having a resin layer into contact with an etchant to dissolve a part of the metal particles and the metal foil, thereby forming a through-hole in the metal foil, after the above-mentioned resin layer forming step, and is a step of forming a through-hole in the metal foil by a so-called chemical etching treatment.

[Etchant]

As the etchant, an acid or alkali chemical solution or the like can be appropriately used as long as it is an etchant suitable for a metal species of the metal particles and the metal foil.

Examples of the acid include hydrochloric acid, sulfuric acid, nitric acid, hydrofluoric acid, hydrogen peroxide, and acetic acid.

Examples of the alkali include caustic soda and caustic potash.

Examples of the alkali metal salt include alkali metal silicates such as sodium metasilicate, sodium silicate, potassium metasilicate, and potassium silicate; alkali metal carbonates such as sodium carbonate and potassium carbonate; alkali metal aluminates such as sodium aluminate and potassium aluminate; alkali metal aldonates such as sodium gluconate and potassium gluconate; and alkali metal hydrogen phosphates such as secondary sodium phosphate, secondary potassium phosphate, tertiary sodium phosphate, and tertiary potassium phosphate.

In addition, an inorganic salt such as iron (III) chloride or copper (II) chloride can also be used.

In addition, these etchant compounds may be used alone or in combination of two or more thereof

[Treatment Method]

The treatment of forming a through-hole is carried out by bringing a metal foil having a resin layer into contact with the above-mentioned etchant.

The method of bringing the metal foil into contact with the etchant is not particularly limited, and examples thereof include a dipping method and a spray method. Especially, a dipping method is preferable.

The dipping time is preferably 15 seconds to 10 minutes and more preferably 1 minute to 6 minutes.

In addition, the liquid temperature of the etchant in a case of dipping is preferably 25° C. to 70° C. and more preferably 30° C. to 60° C.

[Resin Layer Removing Step]

The resin layer removing step is a step of removing the resin layer to produce a metal foil having through-holes, after the above-mentioned through-hole forming step.

The method of removing the resin layer is not particularly limited, but in a case where the above-mentioned alkaline water-soluble polymer is used as the polymer component, a method of dissolving and removing the resin layer using an alkaline aqueous solution is preferable.

[Protective Layer Removing Step]

The protective layer removing step is a step of removing the protective layer to produce a metal foil having through-holes, after the above-mentioned through-hole forming step.

The method of removing the protective layer is not particularly limited, but in a case where the above-mentioned alkaline water-soluble polymer is used as the polymer component, a method of dissolving and removing the protective layer using an alkaline aqueous solution is preferable. The protective layer can also be removed in the resin layer removing step, in a case where the protective layer has the same layer configuration as the resin layer as described above, except that the metal particles are not embedded therein.

[Alkaline Aqueous Solution]

Specific examples of the alkaline aqueous solution include inorganic alkalis such as sodium hydroxide, potassium hydroxide, sodium carbonate, sodium silicate, sodium metasilicate, and aqueous ammonia; primary amines such as ethylamine and n-propylamine; secondary amines such as diethylamine and di-n-butylamine; tertiary amines such as triethylamine and methyldiethylamine; alcohol amines such as dimethylethanolamine and triethanolamine; quaternary ammonium salts such as tetramethylammonium hydroxide and tetraethylammonium hydroxide; and cyclic amines such as pyrrole and piperidine, in which these compounds may be used alone or in combination of two or more thereof.

In addition, an appropriate amount of alcohols or a surfactant can be added to the above-mentioned alkaline aqueous solution for use.

[Treatment Method]

The treatment of removing the resin layer is carried out, for example, by bringing the metal foil having the resin layer after the through-hole forming step into contact with the above-mentioned alkaline aqueous solution.

The method of bringing the metal foil into contact with the alkaline aqueous solution is not particularly limited, and examples thereof include a dipping method and a spray method. Especially, a dipping method is preferable.

The dipping time is preferably 5 seconds to 5 minutes and more preferably 10 seconds to 2 minutes.

In addition, the temperature of the alkaline aqueous solution at the time of dipping is preferably 25° C. to 60° C. and more preferably 30° C. to 50° C.

In addition, the treatment of removing the protective layer is not particularly limited, but may be the same as the treatment of removing the resin layer. For example, in a case where the above-mentioned alkaline water-soluble polymer is used as the polymer component in the protective layer, a method of dissolving and removing the protective layer using an alkaline aqueous solution is preferable.

[Through-Hole]

The average opening diameter of the through-holes can be adjusted by, for example, the dipping time in the etchant in the above-mentioned through-hole forming step.

In addition, the average opening ratio of the through-holes can be adjusted by, for example, the content of the metal particles in the composition which is used in the above-mentioned resin layer forming step.

[Anti-Corrosion Treatment]

The method of forming the through-holes of the metal foil preferably includes a step of carrying out an anti-corrosion treatment.

In addition, the timing at which the anti-corrosion treatment is carried out is not particularly limited, and the anti-corrosion treatment may be, for example, a treatment to be carried out on the metal foil which is used in the resin layer forming step, or may be a treatment in which triazoles or the like described later is added to the alkaline aqueous solution in the resin layer removing step, or may be a treatment to be carried out after the resin layer removing step.

The anti-corrosion treatment may be, for example, a treatment in which a metal foil is dipped in a solution having a pH of 5 to 8.5 in which at least triazoles are dissolved in a solvent to form an organic dielectric film.

Suitable examples of triazoles include benzotriazole (BTA) and tolyltriazole (TTA).

In addition to the triazoles, various organic rust inhibitors, thiazoles, imidazoles, mercaptans, triethanolamine, and the like can be used.

Water or an organic solvent (particularly, alcohols) can be appropriately used as the solvent for use in the anti-corrosion treatment, but water mainly composed of deionized water is preferable in consideration of the uniformity of the organic dielectric film to be formed, easy control of the thickness during mass production, convenience, and the effect on the environment.

The dissolution concentration of triazoles is appropriately determined depending on the thickness of the organic dielectric film to be formed or the treatment time, but is usually about 0.005% to 1% by weight.

In addition, the temperature of the solution may be room temperature, but the solution may be used after being heated if necessary.

The dipping time of the metal foil in the solution is appropriately determined depending on the dissolution concentration of the triazoles or the thickness of the organic dielectric film to be formed, but may be usually about 0.5 to 30 seconds.

Another specific example of the anti-corrosion treatment may be a method of forming an inorganic dielectric film mainly composed of a hydrated oxide of chromium by dipping a metal foil in an aqueous solution which is obtained by dissolving at least one selected from the group consisting of chromium trioxide, chromate, and dichromate in water.

Here, for example, potassium chromate or sodium chromate is suitable as the chromate, and for example, potassium dichromate or sodium dichromate is preferable as the dichromate. The dissolution concentration thereof is usually set to 0.1% to 10% by mass, and the liquid temperature may be from room temperature to about 60° C. The pH value of the aqueous solution is not particularly limited from an acidic region to an alkaline region, but is usually set to 1 to 12.

In addition, the dipping time of the metal foil is appropriately selected depending on the thickness of the inorganic dielectric film to be formed or the like.

It is preferable to carry out water washing after the completion of each step of the treatments described above. Pure water, well water, tap water, and the like can be used for water washing. A nip device may be used to prevent the treatment liquid from being carried into the next step.

[Roll-to-Roll Treatment]

The production method may be a method in which the treatment of each step is carried out in a so-called single-sheet method using a cut sheet-like metal foil, or may be a method in which a long metal foil is transported in a predetermined transport path in a longitudinal direction and the treatment of each step is carried out, that is, a method of carrying out a so-called roll-to-roll (hereinafter, also referred to as “RtoR”) treatment.

RtoR is a production method in which a metal foil is sent out from a roll formed by winding a long metal foil; while the metal foil being transported in a longitudinal direction, the treatments such as the resin layer forming step and the through-hole forming step described above are continuously and sequentially carried out by each of the treatment devices arranged on the transport path; and the treated metal foil (that is, the metal foil) is wound again into a roll.

As described above, in the production method, a through-hole is formed by dissolving a part of the metal particles and the metal foil in the through-hole forming step. Therefore, since the steps can be continuously carried out without complicating the steps, each step can be easily carried out by RtoR. Productivity can be further improved by using RtoR as the production method.

The composite according to the embodiment of the present invention can be used not only for a molded article such as a metal-like decorative body used for lighting, but also for a photocatalyst carrier, a hydrogen generation catalyst carrier, an enzyme electrode, a carrier of a noble metal absorbent, an antibacterial carrier, an adsorbent, an absorbent, an optical filter, a far-infrared cut filter, a soundproofing material, a sound absorbing material, an electromagnetic wave shield, a building material, and the like.

The present invention is basically configured as described above. Although the laminate, the composite, and the method for producing a composite according to the embodiment of the present invention have been described in detail above, the present invention is not limited to the above-mentioned embodiments, and various modifications or changes can be made without departing from the spirit of the present invention.

### EXAMPLES

The features of the present invention will be described in more detail with reference to the following examples. The materials, reagents, substance amounts and ratios thereof, operations, and the like shown in the following examples can be appropriately changed without departing from the spirit of the present invention. Therefore, the scope of the present invention is not limited to the following examples.

### Example 1

An aluminum foil (JIS (Japanese Industrial Standard) H-4160, alloy number: 1N30, aluminum purity: 99.30%) having an average thickness of 10 μm and a size of 200 mm×300 mm was used as the metal foil.

<Formation of Through-Hole>

The following treatment was carried out on the above-mentioned aluminum surface to produce a metal foil having through-holes.

(a1) Aluminum Hydroxide Film Forming Treatment (Film Forming Step)

Using an electrolytic solution (nitric acid concentration: 1%, sulfuric acid concentration: 0.2%, aluminum concentration: 0.5%) kept at 50° C., and the above-mentioned aluminum foil as a cathode, an electrolytic treatment was carried out to form an aluminum hydroxide film on the aluminum foil. The electrolytic treatment was carried out with a direct-current power source. The direct current density was 55 A/dm², and the voltage was applied for 30 seconds.

The formation of the aluminum hydroxide film was followed by water washing by spraying.

(b1) Electrolytic Dissolution Treatment (Through-Hole Forming Step)

Next, using an electrolytic solution (nitric acid concentration: 1%, sulfuric acid concentration: 0.2%, aluminum concentration: 0.5%) kept at 50° C., and an aluminum foil as an anode, an electrolytic treatment was carried out under the conditions of a current density of 35 A/dm² and a total electric quantity of 380 C/dm² to form through-holes in the aluminum foil and the aluminum hydroxide film. The electrolytic treatment was carried out with a direct-current power source.

The formation of the through-holes was followed by water washing by spraying and then drying.

(c1) Aluminum Hydroxide Film Removing Treatment (Film Removing Step)

Next, the aluminum foil after the electrolytic dissolution treatment was dipped in an aqueous solution (liquid temperature: 35° C.) having a sodium hydroxide concentration of 5% by mass and an aluminum ion concentration of 0.5% by mass for 30 seconds, and then dipped in an aqueous solution (liquid temperature: 50° C.) having a sulfuric acid concentration of 30% and an aluminum ion concentration of 0.5% by mass for 20 seconds, whereby the aluminum hydroxide film was dissolved and removed.

This was followed by water washing by spraying and then drying to produce an aluminum foil having through-holes.

<Formation of Positive Photosensitive Resin Layer>

The following positive photosensitive resin composition 1 was applied onto the surface of the aluminum foil produced above and dried to form a positive photosensitive resin layer having a thickness of about 1 μm, thereby forming a composite.

Positive photosensitive resin composition 1

| | |
|---|---|
| m, p-Cresol novolak (m/p ratio = 6/4, weight-average molecular | 1.0 g |
| weight: 4100) | |
| Esterified product (esterification ratio: 90 mol %) of 2,3,4- | 0.4 g |
| trihydroxybenzophenone with naphthoquinone-1,2-diazide-5- | |
| sulfonyl chloride | |
| Dye in which counter anion of Victoria Pure Blue BOH has been | 0.4 g |
| converted into 1-naphthalenesulfonic acid anion | |
| MEGAFACE F-780-F (surfactant, manufactured by DIC | 0.01 g |
| Corporation) | |
| Methyl ethyl ketone | 13.0 g |
| 1-Methoxy-2-propanol | 0.4 g |

<Exposure and Development Steps>

Using P-806G (manufactured by USHIO INC.), UV (ultraviolet) exposure was carried out for 100 seconds from the surface on which the positive photosensitive resin layer was not formed, and then using DP-4 (manufactured by FUJIFILM Corporation) diluted 8 times with pure water, dipping was carried out for 12 seconds to carry out development to form through-holes in the positive photosensitive resin layer.

### Example 2

A copper foil (JIS C 1100-H, electrolytic copper foil) having an average thickness of 10 μm and a size of 200 mm×200 mm was used as the metal foil.

<(a-1) Resin Layer Forming Step>

A composition 1 for forming a resin layer having the following composition was applied onto one surface of the copper foil and dried to form a resin layer A1 having a thickness of about 1 μm.

In addition, a composition prepared in the same ratio as the following composition 1 for forming a resin layer except for removing copper particles was applied onto the opposite surface of the copper foil and dried to form a protective layer B1 having a thickness of about 1

Composition 1 for forming resin layer

| | |
|---|---|
| m, p-Cresol novolak (m/p ratio = 6/4, weight-average molecular | 1.2 g |
| weight: 4100) | |
| HXR-Cu (copper particles, average particle size: 5.0 μm, | 0.4 g |
| manufactured by Nippon Atomized Metal Powders Corporation) | |
| MEGAFACE F-780-F (surfactant, manufactured by DIC | 0.1 g |
| Corporation) | |
| Methyl ethyl ketone | 1.0 g |
| 1-Methoxy-2-propanol | 5.0 g |

<(b-1) Through-Hole Forming Step>

Next, an etchant (iron (III) chloride concentration: 30% by mass, hydrochloric acid concentration: 3.65% by mass) kept at 40° C. was sprayed onto the copper foil having the resin layer A1 and the protective layer B1 by spraying for 120 seconds, which was followed by water washing by spraying and then drying to form through-holes.

<(c) Resin Layer Removing Step>

Next, the resin layer A1 and the protective layer B1 were dissolved and removed by dipping the copper foil after the formation of the through-holes in an alkaline aqueous solution (sodium hydroxide concentration: 0.4% by mass) at a liquid temperature of 50° C. for 120 seconds.

This was followed by water washing by spraying and then drying to produce a metal foil having through-holes.

<Formation of Positive Photosensitive Resin Layer>

The procedure was carried out in the same manner as in Example 1 described above.

<Exposure and Development Steps>

The procedure was carried out in the same manner as in Example 1 described above.

### Example 3

In Example 3, a composite was produced in the same manner as in Example 1, except that <Formation of resin layer> shown below was carried out, through-holes were formed in a metal foil, and a positive photosensitive resin layer was formed on the surface of the metal foil having through-holes formed therein on which the resin layer was not formed.

<Formation of Resin Layer>

Using a 100 μm thick PET film, a resin layer was laminated on the surface of an aluminum foil (JIS 11-4160, alloy number: 1N30, aluminum purity: 99.30%) having an average thickness of 10 μm and a size of 200 mm×300 mm, which serves as a metal foil, by a method described in JP2013-121673A to produce a composite. The thickness of the resin layer after the production was 100 μm.

### Comparative Example 1

In Comparative Example 1, an aluminum foil having through-holes formed therein was produced in the same manner as in Example 1, except that <Formation of resin layer> shown in Example 3 was carried out and the formation of the positive photosensitive resin layer was not carried out.

### Comparative Example 2

In Comparative Example 2, a copper foil having through-holes formed therein was produced in the same manner as in Example 2, except that <Formation of resin layer> shown below was carried out and the formation of the positive photosensitive resin layer was not carried out.

<Formation of Resin Layer>

In Comparative Example 2, the procedure was carried out in the same manner as in Comparative Example 1, except that LUMIRROR X30 (PET having a thickness of 100 μm, manufactured by Toray Industries, Inc.) was used for the resin layer.

In Examples 1 to 3 and Comparative Examples 1 and 2, the average opening ratio and the average opening diameter were measured by the methods described above. The results are shown in Table 2 below. The transmittance and the tint in Examples 1 to 3 and Comparative Examples 1 and 2 were evaluated. Hereinafter, the evaluation will be described.

[Evaluation]

<Transmittance>

The transmittance of light in a wavelength range of 400 nm to 700 nm was measured, and the average value thereof was calculated. The results are shown in Table 2.

The transmittance of light was measured using NDH4000 (manufactured by Nippon Denshoku Industries Co., Ltd.) in accordance with JIS K 7361.

<Tint>

The tone of the metal foil surface appearance was visually evaluated. The results are shown in Table 2.

In Examples 1 to 3, visual evaluation was carried out from the positive photosensitive resin layer side, and in Comparative Examples 1 and 2, visual evaluation was carried out from the resin layer side.

TABLE 2

| | Metal foil | | | | | |
|---|---|---|---|---|---|---|
| | | | Through-hole | | | |
| | | | Average | Average | | |
| | | | opening | opening | Evaluation | |
| | | Thickness | ratio | diameter | Transmittance | |
| | Type | (μm) | (%) | (μm) | (%) | Tint |
| Example 1 | Aluminum | 10 | 30 | 20 | 30 | Blue |
| | foil | | | | | |
| Example 2 | Copper | 10 | 5 | 20 | 5 | Blue |
| | foil | | | | | |
| Example 3 | Aluminum | 10 | 30 | 20 | 30 | Blue |
| | foil | | | | | |
| Comparative | Aluminum | 10 | 30 | 20 | 30 | Silver |
| Example 1 | foil | | | | | |
| Comparative | Aluminum | 10 | 30 | 20 | 0.1 | Dark ash |
| Example 2 | foil | | | | | |

In each of Examples 1 to 3, the positive photosensitive resin layer was colored blue, but as shown in Table 2, the tint was blue.

On the other hand, the resin layer of Comparative Example 1 had a configuration in which no holes were open and was transparent, and Comparative Example 1 exhibited a silver tint. The resin layer of Comparative Example 2 had a configuration in which no holes were open and was black in color, and Comparative Example 2 exhibited a dark ash tint.

In addition, Comparative Example 1 had the same transmittance as Example 1 of the same aluminum foil, but exhibited a different tint. In Comparative Example 2, since the resin layer was black, the transmittance was small and the tint was different from the color of the resin layer.

### EXPLANATION OF REFERENCES

10: composite
11: metal substrate
11a: surface
11b: surface
12: metal foil
12a: surface
12b: surface
13: through-hole
14: positive photosensitive resin layer
15: through-hole
16: resin layer
20: positive photosensitive resin film
30: resin layer
32: metal particle
33: protective layer
34: through-hole
Dt: thickness direction
E₁: reference line
E₂: reference line
Le: exposure light
Le₁: exposure light
Le₂: exposure light
Q₁: perpendicular line
Q₂: perpendicular line
X: distance

What is claimed is:

1. A laminate comprising:
a metal foil having a plurality of through-holes penetrating therethrough in a thickness direction; and
a positive photosensitive resin layer provided on at least one surface of the metal foil,
wherein, in the metal foil, an average opening diameter of the through-holes is 0.1 to 100 μm and an average opening ratio determined by the through-holes is 0.1% to 90%.

2. A laminate comprising:
a metal foil having a plurality of through-holes penetrating therethrough in a thickness direction;
a resin layer provided on one surface of the metal foil; and
a positive photosensitive resin layer provided on the other surface where the resin layer is not provided among both surfaces of the metal foil,
wherein, in the metal foil, an average opening diameter of the through-holes is 0.1 to 100 μm and an average opening ratio determined by the through-holes is 0.1% to 90%.

3. The laminate according to claim 1, wherein the positive photosensitive resin layer contains two compounds of a phenol type resin (A) and o-naphthoquinonediazide or an infrared absorber (B).

4. The laminate according to claim 2, wherein the positive photosensitive resin layer contains two compounds of a phenol type resin (A) and o-naphthoquinonediazide or an infrared absorber (B).

5. The laminate according to claim 3, wherein the positive photosensitive resin layer contains a coloring material.

6. The laminate according to claim 5, wherein the coloring material contains a dye and a pigment.

7. The laminate according to claim 1, wherein the metal foil has an average thickness of 5 to 1000 μm.

8. The laminate according to claim 2, wherein the metal foil has an average thickness of 5 to 1000 μm.

9. The laminate according to claim 3, wherein the metal foil has an average thickness of 5 to 1000 μm.

10. The laminate according to claim 1, wherein the metal foil is a foil selected from the group consisting of an aluminum foil, a copper foil, a silver foil, a gold foil, a platinum foil, a stainless steel foil, a titanium foil, a tantalum foil, a molybdenum foil, a niobium foil, a zirconium foil, a tungsten foil, a beryllium copper foil, a phosphor bronze foil, a brass foil, a nickel silver foil, a tin foil, a lead foil, a zinc foil, a solder foil, an iron foil, a nickel foil, a Permalloy foil, a nichrome foil, an Alloy 42 foil, a Kovar foil, a Monel foil, an Inconel foil, and a Hastelloy foil, or a foil in which a foil selected from the above group and a foil of a metal of a type different from the foil selected from the above group are laminated.

11. The laminate according to claim 2, wherein the metal foil is a foil selected from the group consisting of an aluminum foil, a copper foil, a silver foil, a gold foil, a platinum foil, a stainless steel foil, a titanium foil, a tantalum foil, a molybdenum foil, a niobium foil, a zirconium foil, a tungsten foil, a beryllium copper foil, a phosphor bronze foil, a brass foil, a nickel silver foil, a tin foil, a lead foil, a zinc foil, a solder foil, an iron foil, a nickel foil, a Permalloy foil, a nichrome foil, an Alloy 42 foil, a Kovar foil, a Monel foil, an Inconel foil, and a Hastelloy foil, or a foil in which a foil selected from the above group and a foil of a metal of a type different from the foil selected from the above group are laminated.

12. The laminate according to claim 3, wherein the metal foil is a foil selected from the group consisting of an aluminum foil, a copper foil, a silver foil, a gold foil, a platinum foil, a stainless steel foil, a titanium foil, a tantalum foil, a molybdenum foil, a niobium foil, a zirconium foil, a tungsten foil, a beryllium copper foil, a phosphor bronze foil, a brass foil, a nickel silver foil, a tin foil, a lead foil, a zinc foil, a solder foil, an iron foil, a nickel foil, a Permalloy foil, a nichrome foil, an Alloy 42 foil, a Kovar foil, a Monel foil, an Inconel foil, and a Hastelloy foil, or a foil in which a foil selected from the above group and a foil of a metal of a type different from the foil selected from the above group are laminated.

13. A composite comprising:
the laminate according to claim 1,
wherein the positive photosensitive resin layer has a plurality of through-holes penetrating therethrough in a thickness direction, an average opening diameter of the through-holes is 0.1 to 100 μm, and an average opening ratio of the through-holes is 0.1% to 90%.

14. A composite comprising:
the laminate according to claim 2,
wherein the positive photosensitive resin layer has a plurality of through-holes penetrating therethrough in a thickness direction, an average opening diameter of the through-holes is 0.1 to 100 μm, and an average opening ratio of the through-holes is 0.1% to 90%.

15. The composite according to claim 13, wherein the positive photosensitive resin layer contains two compounds of a phenol type resin (A) and o-naphthoquinonediazide or an infrared absorber (B).

16. The composite according to claim 14, wherein the positive photosensitive resin layer contains two compounds of a phenol type resin (A) and o-naphthoquinonediazide or an infrared absorber (B).

17. The composite according to claim 13, which has a light transmittance of 0.1% to 90%.

18. The composite according to claim 14, which has a light transmittance of 0.1% to 90%.

19. A method for producing a composite which has a metal foil having a plurality of through-holes penetrating therethrough in a thickness direction, an average opening diameter of the through-holes of 0.1 to 100 μm, and an average opening ratio determined by the through-holes of 0.1% to 90%, and a positive photosensitive resin layer provided on at least one surface of the metal foil, the method comprising:
exposing the positive photosensitive resin layer from a metal foil side; and
developing the exposed positive photosensitive resin layer with an alkaline aqueous solution.

20. The method for producing a composite according to claim 19, wherein ultraviolet light or infrared light is used for the exposure.
